(19) United States
(12) Patent Application Publication
(10) Pub. No.: US 2018/0327903 A1
(43) Pub. Date: Nov. 15, 2018

(54) BATCH TYPE PROCESSING APPARATUS

(71) Applicant: Tokyo Electron Limited, Minato-ku (JP)

(72) Inventors: Tsutomu Satoyoshi, Nirasaki City (JP); Hiroshi Ishida, Tokyo (JP)

(73) Assignee: Tokyo Electron Limited, Minato-ku (JP)

(21) Appl. No.: 16/040,644

(22) Filed: Jul. 20, 2018

Related U.S. Application Data
(62) Division of application No. 13/525,643, filed on Jun. 18, 2012.

(30) Foreign Application Priority Data
Jun. 21, 2011 (JP) 2011-137102
Apr. 18, 2012 (JP) 2012-095009

(51) Int. Cl. C23C 16/455

(52) U.S. Cl. CPC C23C 16/45517; C23C 16/45546

(57) ABSTRACT

A batch type processing apparatus for simultaneously processing a plurality of target objects to be processed, includes a main chamber; a plurality of stages, arranged in the main chamber in a height direction of the main chamber, for mounting thereon the target objects; and a plurality of covers, provided to the stages, for covering the target objects mounted on the stages. The stages and the covers surround the target objects mounted on the stages, thereby forming small processing spaces each of which has a capacity smaller than a capacity of the main chamber.

### CROSS-REFERENCE TO RELATED APPLICATIONS

This application is a divisional of and claims the benefit of priority under 35 U.S.C. § 120 from U.S. application Ser. No. 13/525,643 filed Jun. 18, 2012, the entire contents of which are incorporated herein by reference. U.S. application Ser. No. 13/525,643 claims the benefit of priority under 35 U.S.C. § 119 from Japanese Patent Applications Nos. 2011-137102 filed Jun. 21, 2011 and 2012-095009 filed Apr. 18, 2012; the entire content of each of which are incorporated herein by reference.

### FIELD OF THE INVENTION

The present invention relates to a batch type processing apparatus.

### BACKGROUND OF THE INVENTION

Conventionally, in order to perform treatment such as film formation, etching or the like on an object to be processed, e.g., a glass substrate used for manufacturing a solar cell module or a flat panel display (hereinafter, referred to as a FPD) such as a liquid crystal display, an organic EL or the like, plasma processing has been widely used in view of a processing speed or controllability. Further, a single type wafer processing apparatus capable of dealing with a demand for a throughput while improving a plasma processing performance with a simple structure has been used.

However, it is obvious that batch type processing is more effective than single type wafer processing in terms of throughput. A batch type processing apparatus is recently being developed. The batch type processing apparatus is disclosed in, e.g., Japanese Patent Application Publication No. H8-8234.

Meanwhile, as a TFT (thin film transistor) formed on a glass substrate is miniaturized, plasma damage inflicted on a thin film, e.g., a gate or the like, formed on the glass substrate is increased. Moreover, low-temperature treatment is required for manufacturing an organic EL or the like, so that it is reconsidered to perform treatment using a gas without using a plasma.

A processing apparatus for performing treatment using a gas without generating a plasma has a simpler structure than that of a processing apparatus using a plasma. Hence, a batch type processing apparatus can be employed for such processing apparatus.

However, when a plurality of glass substrates is provided in a large processing chamber and processed simultaneously, the usage efficiency of a processing gas is decreased. This is because a capacity of the processing chamber is increased.

In a thin film formation field, attention has been paid to an atomic layer deposition method (hereinafter, referred to as “ALD method”) for forming a thin film at an atomic layer level by alternately supplying at least two precursor gases on a substrate surface and allowing the precursor gases to be adsorbed on an adsorption site formed on the substrate surface. The ALD method is considered to be very effective in forming a finer device due to its high step coverage, high film thickness uniformity and excellent thin film controllability. For example, even in the case of forming a thin film on a glass substrate having a size of about 730 mm×920 mm to 2200 mm×2500 mm which is considerably larger than that of a semiconductor wafer, the ALD method is employed to obtain a high-quality thin film.

However, if the ALD method is applied to a plurality of large-sized glass substrates simultaneously, it is difficult to uniformly supply the precursor gases to the surfaces of the glass substrates or perform uniform exhaust due to a large area of the glass substrates and a large capacity of the processing chamber accommodating therein the glass substrates. Therefore, it is difficult to uniformly form adsorption sites on the surfaces of the glass substrates or ensure uniform or stable reaction between the precursor gases and the adsorption sites. As a result, a desired quality of a thin film cannot be obtained.

### SUMMARY OF THE INVENTION

In view of the above, the present invention provides a batch type processing apparatus capable of effectively using a processing gas and applying an ALD method to a large-size object to be processed.

In accordance with one aspect of the present invention, there is provided a batch type processing apparatus for simultaneously processing a plurality of target objects to be processed, including: a main chamber; a plurality of stages, arranged in the main chamber in a height direction of the main chamber, for mounting thereon the target objects; and a plurality of covers, provided to the stages, for covering the target objects mounted on the stages, wherein the stages and the covers surround the target objects mounted on the stages, thereby forming small processing spaces each of which has a capacity smaller than a capacity of the main chamber.

In accordance with the present invention, it is possible to provide a batch type processing apparatus capable of effectively using a processing gas and applying an ALD method to a large-size object to be processed.

### BRIEF DESCRIPTION OF THE DRAWINGS

The objects and features of the present invention will become apparent from the following description of embodiments, given in conjunction with the accompanying drawings, in which:

FIG. 1 is a horizontal cross sectional view showing an example of a processing system including a batch type processing apparatus in accordance with a first embodiment of the present invention;

FIG. 2 is a cross sectional view taken along line II-II in FIG. 1;

FIGS. 3A and 3B illustrate a state where covers are raised and a state where the covers are lowered, respectively;

FIGS. 4A and 4B illustrate a state where lifters are raised and a state where the lifers are lowered, respectively;

FIG. 5 is a perspective view showing a state where a stage and a cover are separated;

FIG. 6A is a top view showing vicinity of a gas injection hole forming area, and FIG. 6B is a cross sectional view taken along line VIB-VIB in FIG. 6A;

FIG. 7A is a top view showing vicinity of a gas exhausting groove, and FIG. 7B is a cross sectional view taken along line VIIB-VIIB in FIG. 7B;

FIG. 8 illustrates a gas flow in a small processing space;

FIGS. 9A to 9F are cross sectional views showing an example of an operation of loading and unloading an object to be processed;

FIG. 10A is a top view of a batch type processing apparatus in accordance with a first modification, and FIG. 10B is a cross sectional view taken along line XB-XB in FIG. 10A; FIGS. 11A to 11C are cross sectional views showing examples of a small processing space;

FIGS. 12A and 12B show a state where stages of a batch type processing apparatus in accordance with a third modification are lowered and a state where the stage is raised, respectively;

FIG. 13 shows a state where lifters of the batch type processing apparatus in accordance with the third modification are raised;

FIG. 14 is a cross sectional view showing an example of vertical gas injection;

FIG. 15 is a cross sectional view showing an example of horizontal gas injection;

FIGS. 16A and 16B show a state where lifters of a batch type processing apparatus in accordance with a fourth modification are lowered and a state where the lifters are raised, respectively;

FIG. 17 is a cross sectional view showing vicinity of a pin-shaped lifter accommodating portion of the stage;

FIGS. 18A and 18B show a state where covers of a batch type processing apparatus in accordance with a fifth modification are raised and a state where the covers are lowered, respectively;

FIG. 19 is a cross sectional view showing a stage and a cover of a batch type processing apparatus in accordance with an example of a second embodiment of the present invention and a vicinity thereof;

FIG. 20 is a cross sectional view showing a stage and a cover of a batch type processing apparatus in accordance with an example of a third embodiment of the present invention and a vicinity thereof;

FIG. 21 is a cross sectional view showing a stage and a cover of a batch type processing apparatus in accordance with a modification of a third embodiment of the present invention and a vicinity thereof;

FIG. 22 is a cross sectional view showing a stage and a cover of a batch type processing apparatus in accordance with an example of a fourth embodiment of the present invention and a vicinity thereof;

FIGS. 23A and 23B are cross sectional views taken along line XXIII-XXIII in FIG. 22;

FIGS. 24A and 24B are enlarged cross sectional views showing a vicinity of a gas exhausting groove;

FIG. 25 is a cross sectional view showing a stage and a cover of a batch type processing apparatus in accordance with a first modification of the fourth embodiment;

FIG. 26 is a cross sectional view showing a stage and a cover of a batch type processing apparatus in accordance with a second modification of the fourth embodiment;

FIG. 27 is a cross sectional view showing a stage and a cover of a batch type processing apparatus in accordance with a third modification of the fourth embodiment;

FIG. 28 is a cross sectional view showing a stage and a cover of a batch type processing apparatus in accordance with a fourth modification of the fourth embodiment;

FIG. 29 is a cross sectional view showing a stage and a cover of a batch type processing apparatus in accordance with a fifth modification of the fourth embodiment;

FIG. 30 is a cross sectional view showing a stage and a cover of a batch type processing apparatus in accordance with an example of the first embodiment;

FIG. 31 is a cross sectional view showing a stage and a cover of a batch type processing apparatus in accordance with an example of a fifth embodiment of the present invention;

FIG. 32 is an enlarged cross sectional view showing a vicinity of a gas exhausting groove of a batch type processing apparatus in accordance with an example of the fifth embodiment;

FIG. 33 is an enlarged cross sectional view showing a vicinity of a gas exhausting groove of a batch type processing apparatus in accordance with a first modification of the fifth embodiment;

FIG. 34 is a cross sectional view showing a stage and a cover of a batch type processing apparatus in accordance with a second modification of the fifth embodiment;

FIG. 35 is a cross sectional view showing a stage and a cover of a batch type processing apparatus in accordance with a third modification of the fifth embodiment;

FIG. 36 is an enlarged cross sectional view showing a vicinity of a gas exhausting groove of the batch type processing apparatus in accordance with the third modification of the fifth embodiment;

FIG. 37 is a cross sectional view showing a stage and a cover of the batch type processing apparatus in accordance with the fourth modification of the fifth embodiment of the present invention;

FIG. 38 is a cross sectional view showing a stage and a cover of the batch type processing apparatus in accordance with an example of the first embodiment;

FIG. 39 is a cross sectional view showing a stage and a cover of a batch type processing apparatus in accordance with an example of a sixth embodiment of the present invention; and

FIG. 40 is a top view showing a modification of a pick.

### DETAILED DESCRIPTION OF THE EMBODIMENTS

Hereinafter, embodiments of the present invention will be described with reference to the accompanying drawings which form a part hereof. Throughout the drawings, like reference numerals refer to like parts.

### First Embodiment

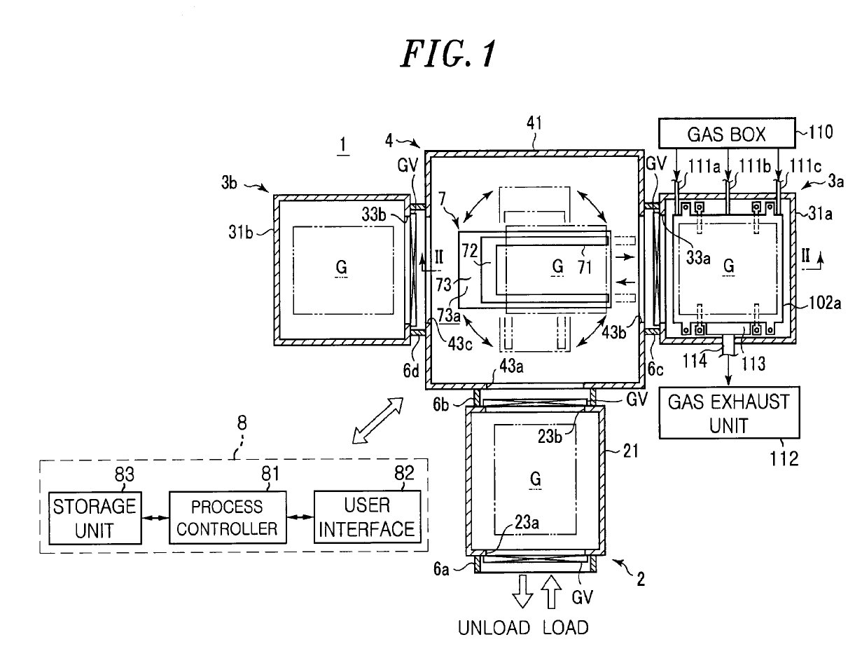

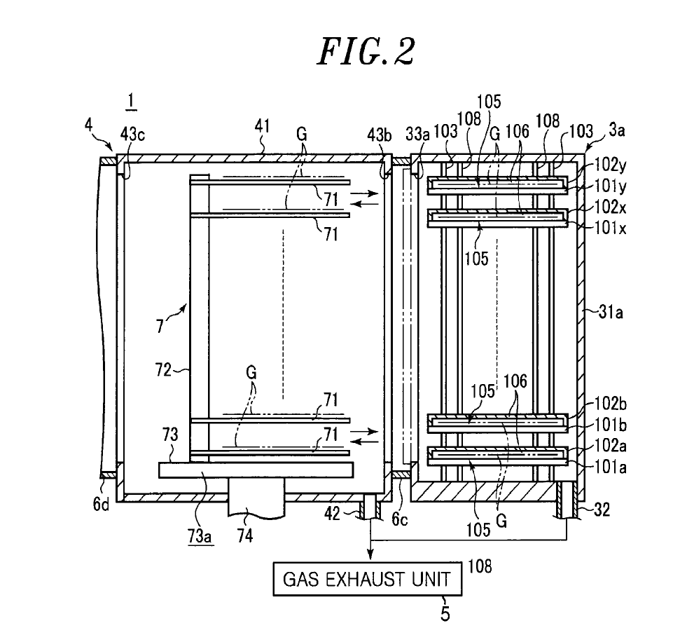

FIG. 1 is a horizontal cross sectional view showing an example of a processing system including a batch type processing apparatus in accordance with an embodiment of the present invention. FIG. 2 is a cross sectional view taken along line II-II in FIG. 1. The processing system shown in FIGS. 1 and 2 performs film formation or heat treatment on an object to be processed, e.g., a glass substrate used for a solar cell module or fabrication of a FPD.

As shown in FIG. 1, a processing system 1 includes a load-lock chamber 2, a batch type processing apparatus 3a and 3b, and a common transfer chamber 4. In the load-lock chamber 2, a pressure is switched between the atmospheric pressure state and the depressurized state. The batch type processing apparatus 3a and 3b performs film formation or heat treatment on an object to be processed G, e.g., a glass substrate. For example, the object to be processed G is formed in a rectangle having a dimension of about 730 mm×920 mm to 2200 mm×2500 mm.

In the present embodiment, the load-lock chamber 2, the batch type processing apparatuses 3a and 3b, and the common transfer chamber 4 are configured as vacuum devices, and respectively include airtight chambers 21, 31a, 31b and 41 capable of accommodating therein objects to be processed G in a predetermined depressurized state. In FIG. 2, a gas exhaust unit 5 such as a vacuum pump or the like is connected to the chambers 21, 31a, 31b, and 41 via a gas exhaust port to set the interior of the chambers to a depressurized state. A gas exhaust port 32 provided to the chamber 31a and a gas exhaust port 42 provided to the chamber 41 are illustrated.

Moreover, openings 23a, 23b, 33a, 33b, 43a, 43b and 43c are formed at the chambers 21, 31a, 31b, and 41. The objects to be processed G are loaded and unloaded via the openings.

The chamber 21 of the load-lock chamber 2 communicates with the outside of the processing system 1, i.e., the atmospheric side, via the opening 23a and a gate valve chamber 6a. The gate valve chamber 6a accommodates therein a gate valve GV for opening and closing the opening 23a. Further, the chamber 21 communicates with the chamber 41 via the opening 23b, a gate valve chamber 6b, and the opening 43a. The gate valve chamber 6b accommodates therein a gate valve GV for opening and closing the opening 23b.

The chamber 31a of the batch type processing apparatus 3a communicates with the chamber 41 via the opening 33a, a gate valve chamber 6c accommodating therein a gate valve GV for opening and closing the opening 33a, and the opening 43b.

In the same manner, the chamber 31b of the batch type processing apparatus 3b communicates with the chamber 41 via the opening 33b, a gate valve chamber 6d accommodating therein a gate valve GV for opening and closing the opening 33b, and the opening 43c.

In the present embodiment, the chamber 41 of the common transfer chamber 4 has a rectangular shape when viewed from above. The openings 43a, 43b and 43c are formed at three sides among four sides of the rectangle. A transfer unit 7 is installed in the common transfer chamber 4. The transfer unit 7 transfers an object to be processed G from the load-lock chamber 2 to the batch type processing apparatus 3a or 3b, from the batch type processing apparatus 3a or 3b to the batch type processing apparatus 3b or 3a, or from the batch type processing apparatus 3a or 3b to the load-lock chamber 2. Therefore, the transfer unit 7 is configured to be able to perform an operation of vertically moving the object to be processed G, an operation of rotating the object to be processed G, and an operation of moving into or retreating from the load-lock chamber 2 and the batch type processing apparatus 3a and 3b.

The transfer unit 7 includes a pick unit 72 having picks 71 serving as supporting members for supporting the object to be processed G, a slide unit 73 for sliding the pick unit 72, and a drive unit 74 for driving the slide unit 73. The picks 71 are provided to multiple stages in a height direction of the chamber 41, so that a plurality of objects to be processed G is horizontally mounted on the picks 71 in the height direction of the chamber 41. Accordingly, the objects to be processed G can be transferred together.

The slide unit 73 includes a slide base 73a. The pick unit 72 is attached to the slide base 73a and slides thereon back and forth. Hence, the pick unit 72 moves back and forth from the chamber 41 to the chambers 21, 31a and 31b. Further, the slide unit 73 is moved vertically and rotated by the drive unit 74. As a consequence, the slide unit 73 is moved vertically and rotated in, e.g., the common transfer chamber 4.

The components of the processing system 1 and the transfer device 7 are controlled by a control unit 8. The control unit 8 includes a process controller 81 having, e.g., a micro processor (computer). The controller 81 is connected to a user interface 82 having a keyboard through which an operator inputs commands for managing the processing system 1, a display for visually displaying an operation state of the processing system 1, and the like. Further, the process controller 81 is connected to a storage unit 83. The storage unit 83 stores therein control programs to be used in realizing various processes performed by the processing system 1 under the control of the process controller 81, or recipes to be used in performing a process in each component of the processing system 1 under processing conditions. The recipes are stored in a storage medium of the storage unit 83. The storage medium may be a hard disc or a semiconductor memory, or a portable device such as a CD-ROM, a DVD, a flash memory or the like. Besides, the recipes may be properly transmitted from other devices via, e.g., a dedicated line. If necessary, a recipe is read out from the storage unit 83 in accordance with an instruction from the user interface 82, and the processing corresponding to the read-out recipe is executed by the process controller 81. Accordingly, the processing system 1 and the transfer device 7 perform desired processing and control under the control of the process controller 81.

Among the batch type processing apparatuses 3a and 3b of the processing system 1 in accordance with the first embodiment of the present invention, the batch type processing apparatus 3a is a batch type processing apparatus in accordance with an example of the first embodiment of the present invention. As for the batch type processing apparatus 3b, either a conventional batch type processing apparatus or the batch type processing apparatus of the first embodiment can be used. Hereinafter, the batch type processing apparatus 3a will be described in detail.

As shown in FIGS. 1 and 2, the batch type processing apparatus 3a includes the chamber 31a. Hereinafter, the chamber 31a is referred to as a main chamber 31a.

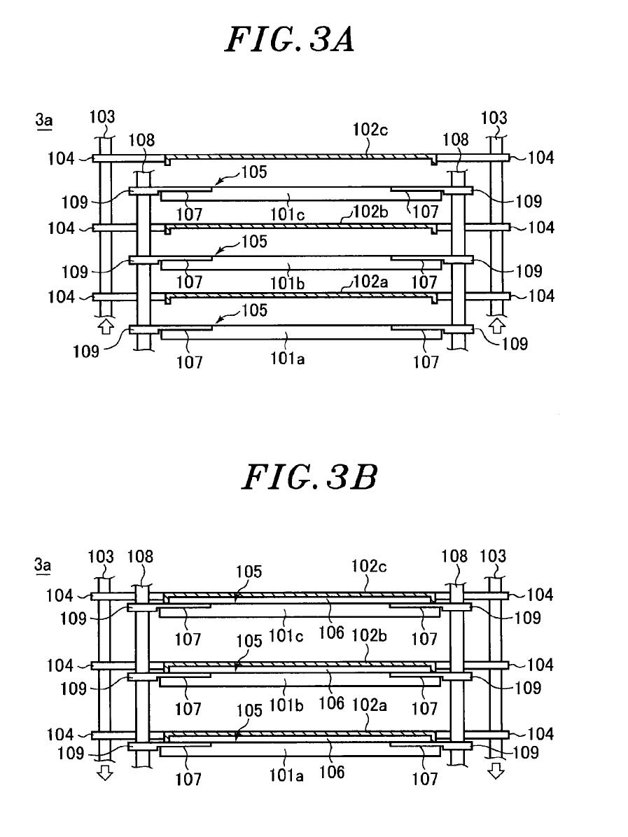

As shown in FIGS. 2 and 3, a plurality of stages 101a, 101b, . . . , 101x, 101y and a plurality of covers 102a, 102b, 102x, 102y are provided in the main chamber 31a. The stages 101a, 101b, . . . , 101x, 101y are arranged in the height direction of the main chamber 31a and mount thereon the objects to be processed G. The covers 102a, 102b, . . . , 102x, 102y are provided to the stages 101a to 101y to cover the objects to be processed G mounted on the stages 101a to 101y, respectively.

In the present embodiment, the stages 101a to 101y are fixed to the main chamber 31a by fixing units (not shown), and the covers 102a to 102y are vertically moved in the main chamber 31a. For example, four cover elevation columns 103 for vertically moving the covers 102a to 102y together are provided in the main chamber 31a. The covers 102a to 102y are fixed to the cover elevation columns 103 via fixing units 104. By vertically moving the cover elevation columns 103 in the height direction of the main chamber 31a, the covers 102a to 102y are vertically moved together.

When the covers 102a to 102y are raised at one time from the stages 101a to 101y, the stages 101a to 101y are exposed to the inner space of the main chamber 31a. Hence, the objects to be processed G can be transferred onto target object mounting surfaces 105 of the stages 101a to 101y. FIG. 3A shows a state where the covers 102a to 102c among the covers 102a to 102y are raised together.

On the contrary, when the stages 101a to 101y and the covers 102a to 102y are brought into airtight contact with each other by lowering the covers 102a to 102y together, small processing spaces, each having a smaller capacity than that of the inner space of the main chamber 31a, are formed so as to surround the objects to be processed G mounted on the target object mounting surfaces 15 of the stages 101a to 101y. FIG. 3B shows a state where the covers 102a to 102c among the covers 102a to 102y are lowered together.

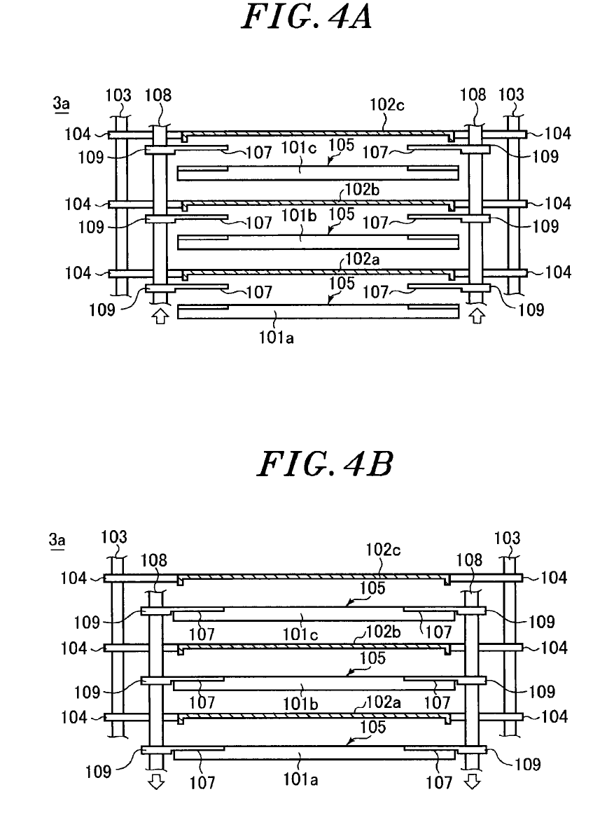

Lifters 107 for transferring the objects to be processed G with respect to the picks 71 are provided at the peripheral portions of the stages 101a to 101y. In the present embodiment, four lifters are provided, for example, to support the peripheral portions of the objects to be processed G. In the main chamber 31a, four lifter elevation columns 108, for example, are provided to vertically move the lifters 107 together. The lifters 107 are fixed to the lifter elevation columns 108 via fixing units 109. By vertically moving the lifter elevation columns 108 in the height direction of the main chamber 31a, the lifters 107 are vertically moved together. FIGS. 4A and 4B show a state where the lifters 107 provided at the peripheral portions of the stages 101a to 101c are raised together and a state where the lifters 107 are lowered together, respectively.

As shown in FIG. 1, a processing gas is supplied from a gas supply unit, e.g., a gas box 101, into the small processing space 106 via gas supply lines 111a to 111c. In the present embodiment, three gas supply lines are provided. Since, however, the type or the number of gases is changed in accordance with the type of processing performed in the small processing space 106, the number of the gas supply lines may vary. Further, the batch type processing apparatus 3a of the present embodiment performs ALD film formation. Accordingly, a first precursor gas is supplied from the gas supply line 111a; a purge gas is supplied from the gas supply line 111b; and a second precursor gas is supplied from the gas supply line 111c. The type of the precursor gas varies in accordance with a film to be formed. For example, when a silicon oxide film is formed, it is preferable to use a silicon source gas as a first precursor gas and a gas containing an oxidizing agent as a second precursor gas. The purge gas is a nonreactive gas, e.g., nitrogen gas.

The interior of the small processing space 106 is exhausted by the gas exhaust unit 112 via a gas exhaust duct 113 and a gas exhaust line 114. As for the gas exhaust unit 112, the gas exhaust unit 5 shown in FIG. 2 can be used.

FIG. 5 is a perspective view showing a state where the stage 101a and the cover 102a are separated from each other. The other stages 101b to 101y and the other covers 102b to 102y have the same configurations as those of the stage 101a and the cover 102a. Herein, the configurations of the stage 101a and the cover 102a will be described as representative examples.

As shown in FIG. 5, lifter accommodating portions 115 accommodating therein the lowered lifters 107 are formed at the target object mounting surface 105 of the stage 101a. When the lifters 107 are lowered, the lifters 107 are accommodated in the lifter accommodating portions 115. Therefore, the lifters 107 can be prevented from protruding above the target object mounting surfaces 105, and the object to be processed G can be horizontally mounted on the target object mounting surfaces 105.

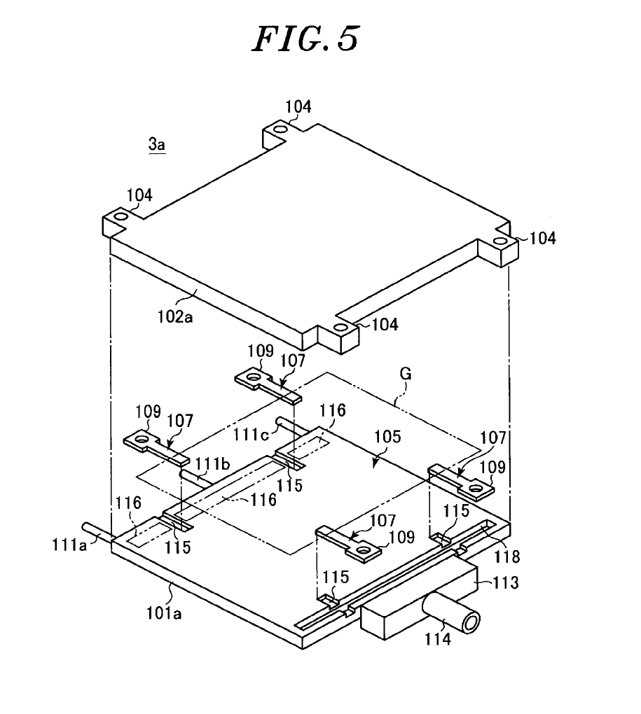

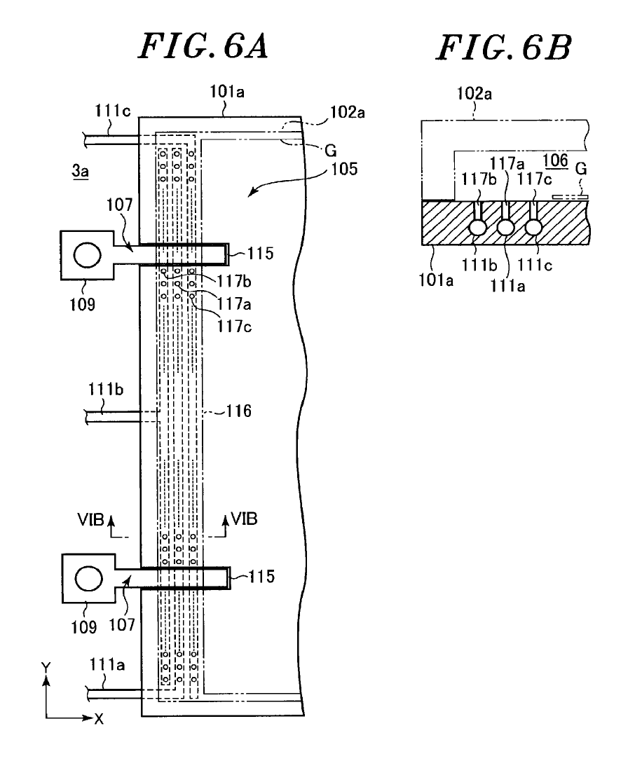

Further, gas injection hole forming areas 116 for injecting gases from the gas supply lines 111a to 111c are formed at a part of the peripheral portion of the target object mounting surface 105. FIG. 6A is a top view showing a vicinity of the gas injection hole forming area, and FIG. 6B is a cross sectional view taken along line VIB-VIB in FIG. 6A.

As shown in FIGS. 6A and 6B, the gas supply line 111a stretched from the gas box 110 extends in a X direction perpendicular to a loading/unloading direction of the object to be processed G near the stage 101a and is connected to one end portion of the stage 101a. Further, the gas supply line 111a is bent in a Y direction (the loading/unloading direction of the object to be processed G) intersecting with, e.g., perpendicular to, the X direction in the stage 101a and extends toward the other end portion of the stage 101a. A plurality of gas injection holes 117a reaching the target object mounting surface 105 is formed at the gas supply line 111a extending in the Y direction.

In the same manner, the gas supply line 111b extends in the X direction and is connected to a central portion of a side of the stage 101a. The gas supply line 111b is branched to the one end portion and the other end portion of the stage 101a immediately before the extended portion of the gas supply line 111b in the stage 101a, and the branched lines extend in the Y direction. A plurality of gas injection holes 117b reaching the target object mounting surface 105 is formed at the gas supply line 111b extending in the Y direction.

In the same manner, the gas supply unit 111c extends in the X direction and is connected to the other end portion of the stage 101a. Unlike the gas supply line 111a, the gas supply line 111c is bent in the Y direction and extends toward one end portion of the stage 101a. A plurality of gas injection holes 117c reaching the target object mounting surface 105 is formed at the gas supply line 111c extending in the Y direction.

The gases supplied to the gas supply lines 111a to 111c are injected from the gas injection holes 117a to 117c into the small processing space 106.

In the present embodiment, the gas supply lines 111a to 111c extend from one end side to the other end side while passing below the lifters 107 without being disconnected by the lifters 107. Accordingly, the gas can be supplied into the small processing space 106 from the portion between the lifters 107, the portion between the lifter 107 and one end side and the portion between the lifter 107 and the other end side. With this, the gas can be more uniformly supplied into the small processing space 106 compared to when the gas is supplied only from the portion between the lifters 107.

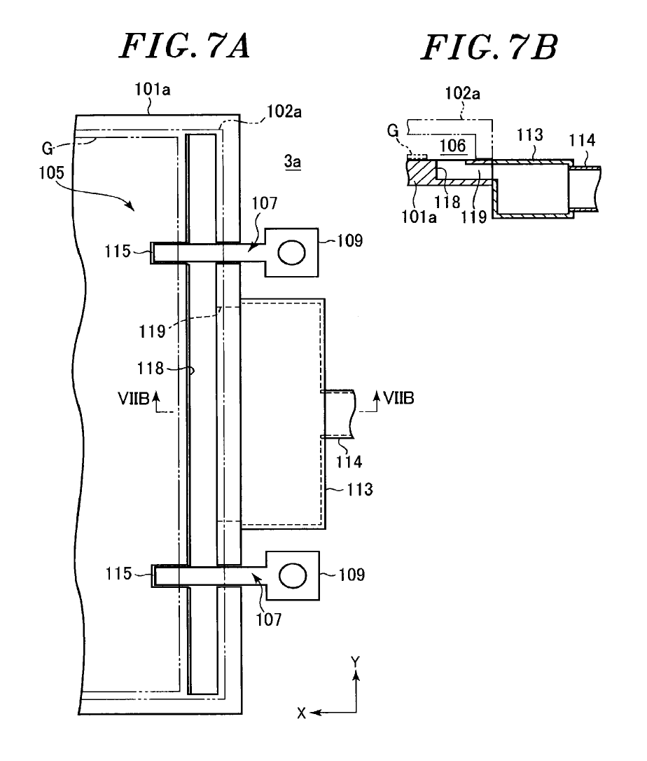

A gas exhausting groove 118 is formed at the peripheral portion of the target object mounting surface 105 which faces the gas injection hole forming area 116. FIG. 7A is a top view showing a vicinity of the gas exhausting groove, and FIG. 7B is a cross sectional view taken along line VIIB-VIIB in FIG. 7A.

The gas exhausting groove 118 is formed from one end portion to the other end portion of the stage 101a along the Y direction. The gas exhaust duct 113 connected to the gas exhaust line 114 is connected to the central portion of a side of the stage 101a, e.g., between the lifters 107. The gas exhausting groove 118 is connected to the gas exhaust duct 113 via a gas exhaust port 119. The gas supplied into the small processing space 106 is sucked from the gas exhausting groove 118, guided to the gas exhaust duct 113 via the gas exhaust port 119, and then exhausted from the gas exhaust duct 113 via the gas exhaust line 114.

In the present embodiment, as in the case of the gas supply lines 111a to 111c, the gas exhausting groove 118 extend from one end portion to the other end portion while passing below the lifters 107 without being disconnected by the lifters 107. Accordingly, the small processing space 106 can be more uniformly exhausted compared to when the gas is exhausted only from the portion between the lifters 107.

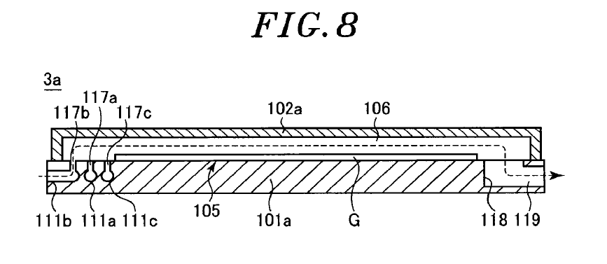

As shown in FIG. 8, when the small processing space 106 is formed, the gas is injected in a vertical direction from the substrate mounting surface 105 through the gas injection holes 117a to 117c. Then, due to the presence of the cover 102a, the gas flows in a horizontal direction toward the gas exhausting groove 118 disposed at the opposite side. Next, the gas flows in a vertical direction above the gas exhausting groove 118 and is exhausted toward the gas exhaust port 119.

Hereinafter, the operation of loading and unloading an object to be processed G will be described. Herein, the operation of loading and unloading an object to be processed G into and from the small processing space 106 formed by the stage 101a and the cover 102a will be described as a representative example. However, the operation of loading and unloading an object to be processed into and from the small processing spaces formed by the other stages 101b to 101y and the other covers 102b to 102y is the same.

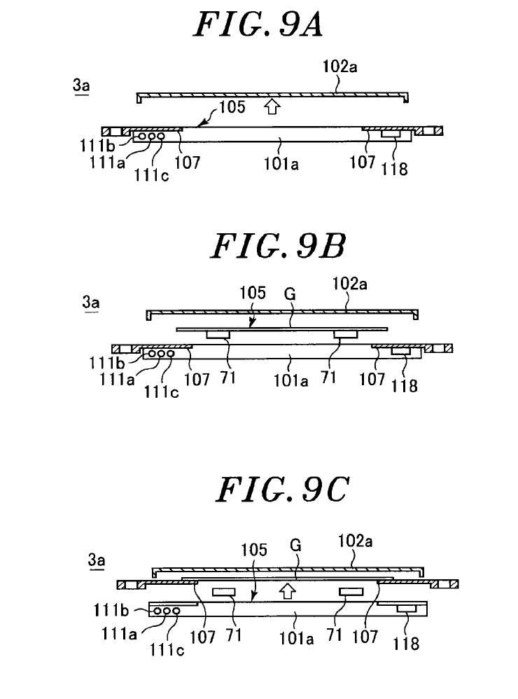

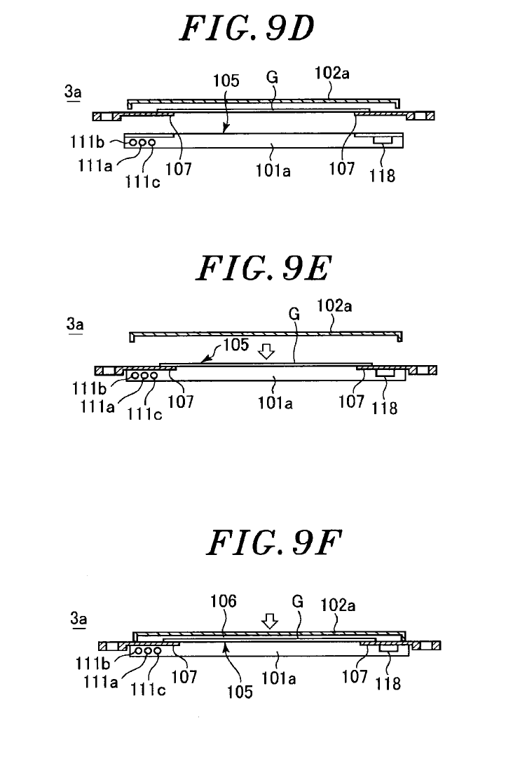

FIGS. 9A to 9F are cross sectional views showing an example of an operation of loading and unloading an object to be processed G.

First, as shown in FIG. 9A, the cover 102a is raised to a position that allows the entrance of the picks 71.

Next, as shown in FIG. 9B, the picks 71 supporting the object to be processed G move from the common transfer chamber 4 to a position above the target object mounting surface 105 of the stage 101a in the main chamber 31a.

Then, as shown in FIG. 9C, the lifters 107 are raised, and the object to be processed G is received from the picks 71.

Thereafter, as shown in FIG. 9D, the lifters 107 receive the object to be processed G, and the picks 71 retreat into the common transfer chamber 4.

Next, as shown in FIG. 9E, the lifters 107 are lowered, and the object to be processed G is mounted on the target object mounting surface 105.

Lastly, as shown in FIG. 9F, the cover 102a and the stage 101a are brought into airtight contact with each other by lowering the cover 102a. As a consequence, the small processing space 106 is formed around the object to be processed G.

In accordance with the batch type processing apparatus 3a, the small processing space 106 having a small capacity is formed so as to surround the object to be processed G. Accordingly, the amount of the processing gas that does not contribute to the film formation can be decreased and the usage efficiency of the processing gas can be increased compared to, e.g., when a plurality of objects to be processed G is exposed to the main chamber 31a.

Since the small processing space 106 has a smaller capacity than that of the main chamber 31a, the gas supply into and the gas discharge from the small processing space 106 can be completed in a shorter period of time compared to the gas supply into and the gas discharge from the main chamber 31a. Accordingly, it is possible to shorten the period of time required for the gas supply and the gas discharge, and also possible to set a tact time to a short period of time. As a result, a batch type processing apparatus that ensures a high throughput can be obtained.

In addition, since the small processing space 106 has a small capacity, the ALD method can be applied to a glass substrate having a size of about, e.g., 730 mm×920 mm to 2200 mm×2500 mm.

Hereinafter, modifications of the batch type processing apparatus 3a will be described.

(First Modification: Improving Airtightness)

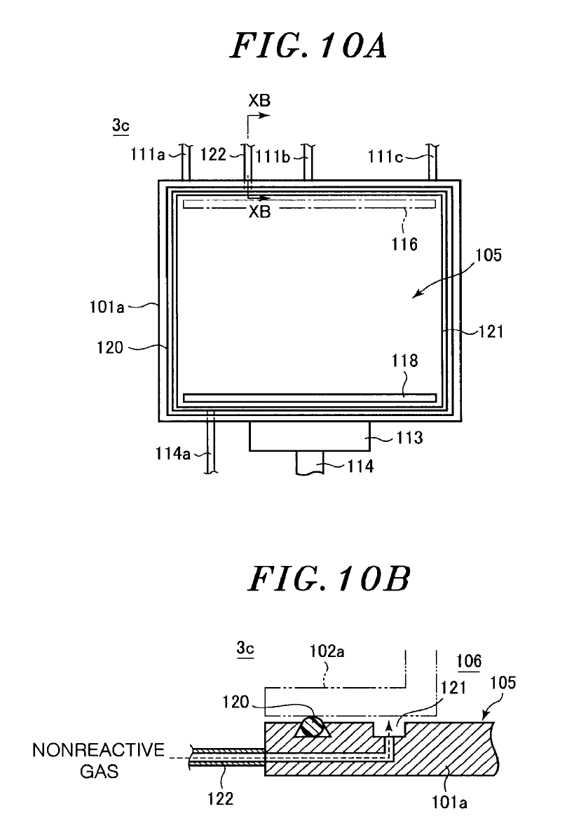

FIG. 10A is a top view of a batch type processing apparatus in accordance with a first modification, and FIG. 10B is a cross sectional view taken along line XB-XB in FIG. 10A.

In order to improve airtightness between the stage 101a and the cover 102a, a sealing member, e.g., an O-ring 120, may be provided at the surface of the stage 101a where the target object mounting surface 105 exists. The O-ring 120 contacts with an abutting surface of the cover 102a which abuts against the stage 101a. Further, as shown in FIG. 10B, in a batch type processing apparatus 3c in accordance with a first modification, an annular groove 121 is provided between the O-ring 120 and the small processing space 106. The cover 102a is provided above the O-ring 120 and an annular groove 121 and comes into contact with the stage 101a.

The annular groove 121 is connected to a gas supply line 122. A nonreactive gas, e.g., nitrogen (N2) gas, is supplied from the gas box 110 to the gas supply line 122. The supplied nitrogen gas is supplied into the annular groove 121. The nitrogen gas supplied into the annular groove 121 is exhausted by the gas exhaust unit 112, for example, via the gas exhaust line 114 and/or a gas exhaust line 114a provided in addition to the gas exhaust line 114.

The nitrogen gas flowing through the annular groove 121 returns to the small processing space 106 a gas that tends to leak from the small processing space 106 through an very small gap between the stage 101a and the cover 102a or guides the gas to the annular groove 121 so that the gas can be discharged together with the nitrogen gas via the gas exhaust line 114 and/or the gas exhaust line 114a.

By providing a sealing member, i.e., the O-ring 120 in the present embodiment, on the surface of the stage 102a where the target object mounting surface 105 exists, the airtightness between the stage 101a and the cover 102a can be increased. In addition to the O-ring 120, the annular groove 121 is provided between the O-ring 120 and the small processing space 106, and the nonreactive gas is made to flow through the annular groove 121. Accordingly, the airtightness between the stage 101a and the cover 102a can be further increased.

By allowing the nonreactive gas to flow through the annular groove 121, the chemically reactive atmosphere, for example, in the small processing space 106 can be prevented from being in direct contact with the O-ring 120. Therefore, it is possible to avoid temporal deterioration of the sealing member, e.g., the O-ring 120, and also possible to reduce the frequency of replacing the O-ring 120.

In the first embodiment, both of the groove 121 and the O-ring 120 are provided. However, only the groove 121 may be provided without providing the O-ring 120. In that case, the nitrogen gas supplied from the groove 121 is distributed to the small processing space 106 and the main chamber. As a consequence, the effect in which the small processing space 106 and the main chamber are separated from each other can be obtained.

(Second Modification: Forming a Small Processing Space)

FIGS. 11A to 11C are cross sectional views showing an example in which a small processing space is formed.

FIG. 11A illustrates the above-described batch type processing apparatus 3a. In the batch type processing apparatus 3a, the stage 101a is flat, and a recess 130a forming a small processing space 106 is formed at the cover 102a.

In this type, as described with reference to FIG. 8, the gas supply into and the gas discharge from the small processing space 106 are performed via the target object mounting surface 105 of the stage 101a.

On the contrary, in the batch type processing apparatus 3d shown in FIG. 11B, the cover 102a is flat, and a recess 130b forming the small processing space 106 is formed at the stage 101a.

In this type, the gas supply into and the gas discharge from the small processing space 106 can be performed via a side surface of the recess 130b of the stage 101a. In that case, a gas injection hole 117 is formed at one side surface of the recess 130b, and the gas exhaust port 119 is formed at the opposite side surface of the recess 130b.

By providing the gas injection hole 117 and the gas exhaust port 119 at the side surfaces of the recess 130b which face each other, the gas supplied from the gas supply line 111 flows from the gas injection hole 117 to the gas exhaust port 119 without changing the direction in the small processing space 106. Therefore, the advantage in which the processing gas easily forms a laminar flow in the small processing space 106 can be obtained. Since the gas flowing in the small processing space 106 forms a laminar flow, the advantage in which controllability of a film thickness or a film quality of a thin film to be formed can be increased can be further obtained.

In the batch type processing apparatus 3e shown in FIG. 11C, the recesses 130a and 130b forming the small processing space 106 are formed at the stage 101a and the cover 102a.

As such, the recesses 130a and 130b forming the small processing space 106 can be provided to the stage 110a and the cover 102a.

(Third Modification: Fixing Covers, Vertically Moving Stages)

A batch type processing apparatus in accordance with a third modification is different from the batch type processing apparatus 3a in accordance with the first embodiment in that the covers 102a to 102y are fixed to the main chamber 31a and the stages 101a to 101y are vertically moved together.

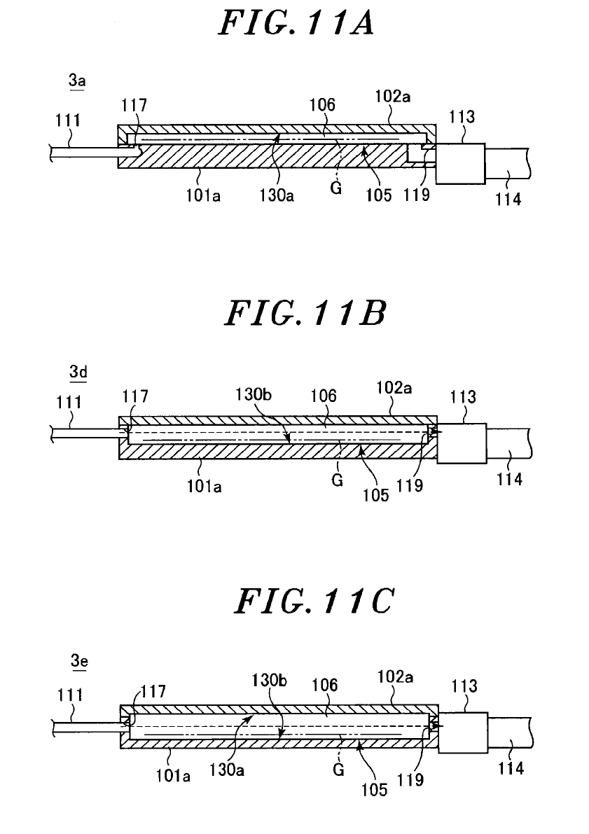

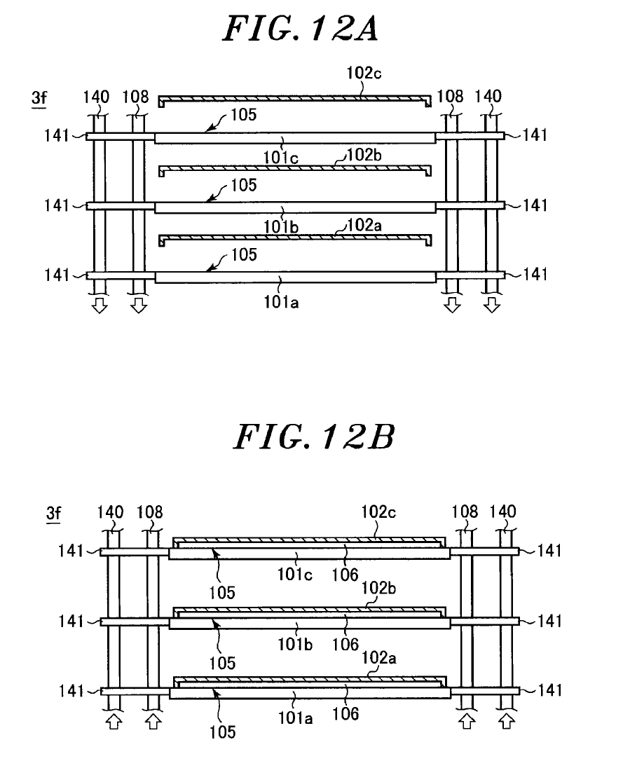

FIGS. 12A and 12B show a state where the stages of the batch type processing apparatus in accordance with the third modification are lowered and a state where the stages are raised, respectively.

As shown in FIGS. 12A and 12B, in the main chamber of the batch type processing apparatus 3f in accordance with the third modification, there are provided four stage elevation columns 140 for vertically moving the stages 101a to 101y together. The covers 102a to 102y are fixed to the main chamber 31a by fixing units (not shown). The stages 101a to 101y are fixed to the stage elevation columns 140 via fixing units 141. By vertically moving the stage elevation columns 140 in the height direction of the main chamber, the stages 101a to 101y are vertically moved together. FIGS. 12A and 12B illustrate a state in which the stages 101a to 101c among the stages 101a to 101y are vertically moved together.

When the lifters 107 are formed at the peripheral portions of the stages 101a to 101y, the lifters 107 are vertically moved along with the vertical movement of the stages 101a to 101y. In order to raise only the lifters 107, the lifter elevation columns 108 are raised in a state where the stages 101a to 101c are lowered, for example. FIG. 13 shows a state in which the lifters 107 are raised in a state where the stages 101a to 101c are lowered. Further, the stages 101a to 101c may be lowered after the lifters 107 and the stages 101a to 101c are lowered together until the lifters 107 reach the position for transferring an object to be processed G. Hence, the effect obtained when the lifters 107 are raised from the stages 101a to 101c can be obtained.

When the covers 102a to 102y are fixed to the main chamber 31a and the stages 101a to 101y are raised together as in the third modification, the covers 102a to 102y are not moved and, accordingly, the gas injection holes 117 and the gas exhaust port 119 can be easily formed at the covers 102a to 102y.

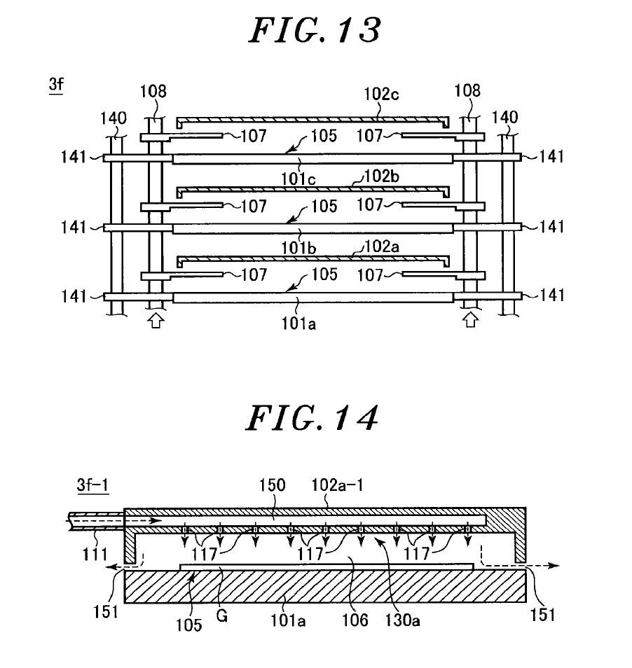

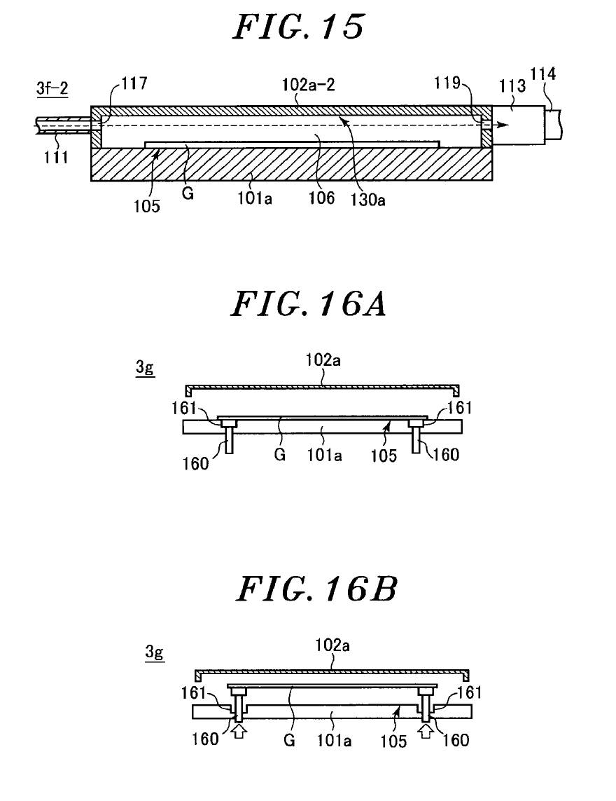

By forming the gas injection hole 117 and the gas exhaust port 119 at the covers 102a to 102y, the gas injection type can be selected between vertical gas injection (so-called gas shower) for injecting a gas in a vertical direction with respect to a surface to be processed of an object to be processed G and horizontal gas injection for injecting a gas in a horizontal direction with respect to a surface to be processed of an object to be processed G. FIG. 14 shows an example of the vertical gas injection, and FIG. 15 shows an example of the horizontal gas injection.

As shown in FIG. 14, a cover 102a-1 of a batch type processing apparatus 3f-1 has a recess 130a forming a small processing space 106 and a gas diffusion space 150 formed therein. The gas diffusion space 150 is connected to a gas supply line 111, a processing gas being supplied from the gas supply line 111. A plurality of gas injection holes 117 is formed at a surface of the cover 102a-1 which faces the object to be processed G. The gas injection holes 117 communicate with the gas diffusion space 150 and the small processing space 106, and are formed in a lattice shape at the cover 102a-1 in accordance with a planar shape of the object to be processed G, for example.

The arrangement shape of the gas injection holes 117 is not limited to the lattice shape, and various shapes may be selected depending on desired gas distribution for the processing.

In the batch type processing apparatus 3f-1, the small processing space 106 is exhausted via the gas exhaust port for exhausting the main chamber shown in FIG. 2. Therefore, the cover 102a-1 does not in complete contact with the stage 101a and forms a small processing space 106 between itself and the stage 101a with a gas exhaust clearance 151 therebetween. The atmosphere in the small processing space 106 is exhausted to the main chamber via the gas exhaust clearance 151 and then is exhausted via the gas exhaust port 32 formed at the main chamber.

As shown in FIG. 15, a cover 102a-2 of a batch type processing apparatus 3f-2 has a recess 130a forming a small processing space 106. A gas injection hole 117 is formed at one surface of the recess 130a, and a gas exhaust port 119 is formed at the other surface of the recess 130a. In the present embodiment, the cover 102a-2 is in airtight contact with the stage 101a. The small processing space 106 is exhausted from the gas exhaust port 119 via a gas exhaust duct 113 and a gas exhaust line 114.

In the batch type processing apparatus 3f-2 as well as the batch type processing apparatus 3f-1, a gas exhaust clearance may be provided between the cover 102a-2 and the stage 101a. The small processing space 106 may be exhausted from the gas exhaust port 32 via the gas exhaust clearance.

In accordance with the third modification, the stages 101a to 101y can be vertically moved, and the covers 102a to 102y are fixed to the main chamber. Thus, the gas injection type can be selected between vertical gas injection and horizontal gas injection. As a result, a degree of freedom in selecting the gas supply types is increased.

(Fourth Modification: A Pin-Shaped Lifter)

FIG. 16A shows a state in which lifters of a batch type processing space in accordance with a fourth modification are lowered, and FIG. 16B shows a state in which the lifters are raised. In FIGS. 16A and 16B, the stage 101a and the cover 102a among the stages 101a to 101y and the covers 102a to 102y are illustrated.

As shown in FIGS. 16A and 16B, a batch type processing apparatus 3g in accordance with a fourth modification is different from the batch type processing apparatus 3a in accordance with the first embodiment in that pin-shaped lifters 160 serve as the lifters 107 and support a plurality of locations on the surface of the object to be processed G in a spot shape without supporting the peripheral portion of the object to be processed G.

As such, the lifter can be replaced by the pin-shaped lifter 160, and this can be applied to the first to the third modification.

As shown in FIG. 17, when the pin-shaped lifter 160 is used as the lifter, a new gas leak path 162 is formed between the small processing space 106 and the main chamber via a small clearance between the pin-shaped lifter 160 and the pin-shaped lifter accommodating portion 161 formed at the stage 101a.

Thus, in order to block the gas leak path 162, sealing members, e.g., O-rings 164, may be provided between the pin-shaped lifter accommodating portion 161 and a head bottom surface 163 of the pin-shaped lifter 160. By providing the O-rings 164, the gas leak from the gas leak path 162 via the small clearance can be suppressed.

(Fifth Modification: Omitting a Target Object Elevation Unit)

In the case of using the pin-shaped lifter 160 as the lifter, it is possible to obtain the advantage in that a target object elevation unit for vertically moving a lifter, e.g., the lifter elevation columns 108 and the unit for driving the lifter elevation columns 108 in the first embodiment, can be omitted from the batch type processing apparatus.

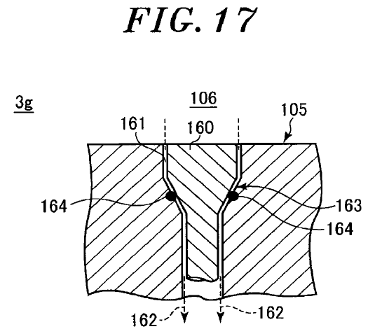

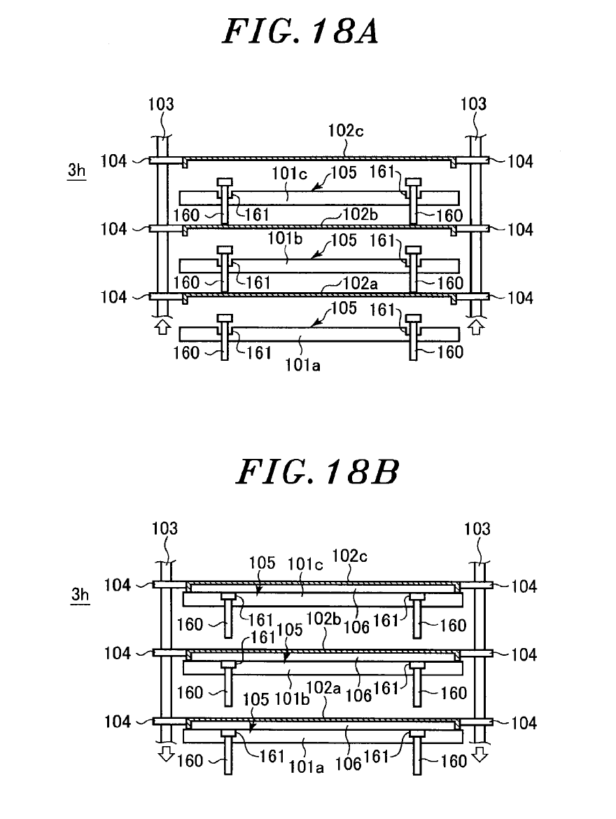

FIG. 18A shows a state in which covers of a batch type processing apparatus in accordance with a fifth modification are raised, and FIG. 18B shows a state in which the covers are lowered. FIGS. 18A and 18B illustrate the state in which pin-shaped lifters 160 provided to the stages 101a to 101c among the lifters 160 provided to the stages 101a˜101y are raised and lowered together.

As shown in FIGS. 18A and 18B, in the batch type processing apparatus 3h in accordance with the fifth modification, the lifters as the target object elevation units are configured as pin-shaped lifters 160 movably suspended from the stages 101a to 101c while penetrating the pin-shaped lifter accommodating portions 161 provided to the stages. When the covers 102a to 102c are raised, the lower ends of the pin-shaped lifters 160 are brought into contact with the top surfaces of the covers 102a to 102c positioned therebelow. Accordingly, the pin-shaped lifters 160 are raised as the covers 102a to 102c are raised.

If the covers are lowered from the state shown in FIG. 18A, the lower ends of the pin-shaped lifters 160 are separated from the top surfaces of the covers 102a to 102c positioned therebelow and, also, the pin-shaped lifters 160 are accommodated in the pin-shaped lifter accommodating portions 161.

In accordance with the fifth modification, the target object elevation unit for vertically moving the pin-shaped lifters 160 is operated in conjunction with the cover elevation unit for vertically moving the covers. For example, in the present embodiment, the pin-shaped lifters 160 are vertically moved by the vertical movement of the covers 102a to 102c, so that the target object elevation unit for vertically moving the lifters, e.g., the lifter elevation columns 108 and the unit for driving the lifter elevation columns 108, can be omitted from the batch type processing apparatus.

By omitting the target object elevation unit from the batch type processing apparatus, the capacity of the main chamber is decreased. Besides, since the driving system in the main chamber is omitted, the generation of particles can be suppressed.

By omitting the driving system in the main chamber, the manufacturing cost of the batch type processing apparatus can be reduced.

### Second Embodiment

In the first embodiment, the gas supply unit is provided to fixed one among the stages 101a to 101y and the covers 102a to 102y.

In the second embodiment, the gas supply unit is provided to vertically movable components between the stages 101a to 101y and the covers 102a to 102y.

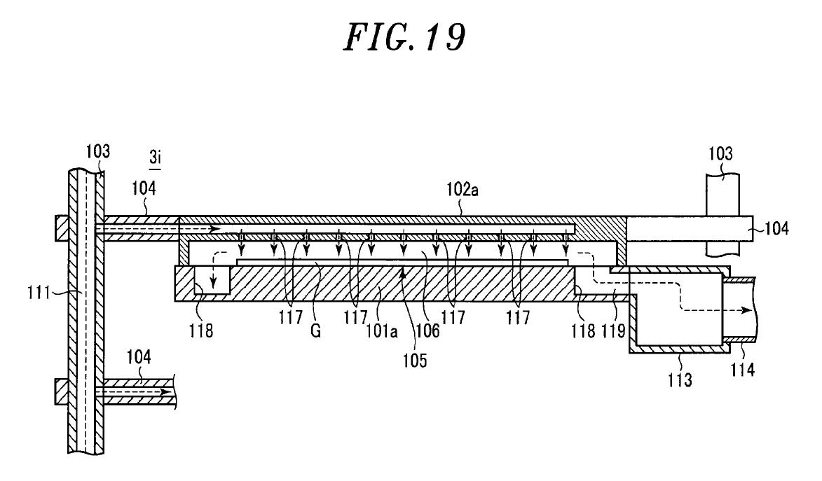

FIG. 19 is a cross sectional view showing a stage and a cover of a batch type processing apparatus in accordance with an example of a second embodiment of the present. In FIG. 19, only the cover 102a among the covers 102a to 102y is illustrated.

As shown in FIG. 19, a batch type processing apparatus 3i in accordance with the second embodiment is particularly different from the batch type processing apparatus 3a in accordance with the first embodiment in that a gas supply line 111 is formed in a fixing unit 104 and a cover elevation column 103 for raising and lowering the covers 102a to 102y together.

As such, by forming the gas supply line 111 in the cover elevation column 103 and the fixing unit 104, the gas supply unit including the gas supply line 111 and gas injection holes 117 can be provided to the vertically movable covers 102a to 102y.

In the present embodiment, the cover 102a is configured as a vertical gas injection type (gas shower) as in the cover 102a-1 shown in FIG. 14. Moreover, the stages 101a to 101y are fixed. Thus, the vertical gas injection type can be employed for the gas injection into the small processing space 106, and the gas discharge from the small processing space 106 can be carried out by sucking the gas from the target object mounting surface 105 via a gas exhausting groove 118 and a gas exhaust port 119.

As in the first embodiment, the gas exhausting groove 118 of the present embodiment may be formed in an annular shape surrounding the circumference of the object to be processed G mounted on the stage 101a without being formed in a single line shape along one side of the stage 101a. This is because the gas supply lines 111a to 111c shown in FIG. 6, for example, are omitted from the stage 101a.

When the vertical gas injection type (gas shower) is employed for the gas injection into the small processing space 106, the uniformity of the gas discharge from the small processing space 106 can be facilitated by using the annular gas exhausting groove 118.

### Third Embodiment

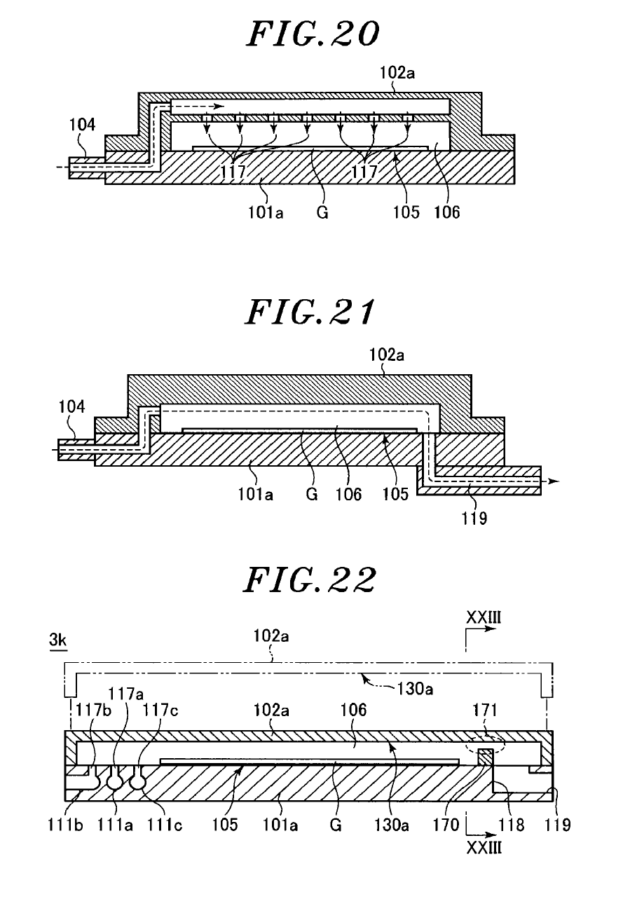

FIG. 20 shows a third embodiment. The third embodiment is different from the first and the second embodiment in that a gas supplied to a stage 101a through a fixing unit 104 is supplied to the cover 102a through a gas passage of a contact portion between the stage 101a and the cover 102a, and then is supplied from a gas shower provided to the cover 102a to a processing space 106 through a plurality of gas injection holes 117. The gas in the processing space 106 may be exhausted by a gas exhaust port (not shown) provided at the stage 101a or may be exhausted through a gap between the cover 102a and the stage 101a. However, airtightness in the gas channel of the contact portion between the cover 102a and the stage 101a needs to be maintained by surrounding the gas channel by a sealing member.

In accordance with the third embodiment, the stage 101a on which the object to be processed G is mounted is fixed, so that a load applied to a driving unit is small and the possibility in which the object to be processed G is damaged is low. Furthermore, since the gas can be supplied from a vertically movable cover through a shower head, the object to be processed G can be uniformly processed.

### Third Embodiment: Modification

FIG. 21 shows a modification of the third embodiment. In the modification of the third embodiment, the gas supplied from the stage 101a to the cover 102a is supplied into the processing space 106 through a single gas inlet hole instead of a shower head. At this time, the supplied gas fills a recess of the cover 102a, so that the gas is supplied to the object to be processed G in a state where the variation in the gas distribution caused by the non-uniform arrangement of the gas inlet ports is suppressed. In FIG. 21, the gas in the processing space 106 is exhausted through the gas exhaust line 114. However, the gas may be exhausted from the gap between the cover 102a and the stage 101a.

In the first to the third embodiment, a temperature control unit may be provided to each of the stages 101a to 101y. As for the temperature control unit, a heating unit such as a resistance heater or the like can be used. In addition, it is possible to use a unit for performing heating or cooling or properly switching heating and cooling by circulating a temperature control medium that is supplied from an external chiller and controlled to a predetermined temperature in passages formed in the stages 101a to 101y. The heating unit using a heater and the temperature control unit using a temperature control medium can be used together.

The temperature control unit using a temperature control medium is preferably used for the configuration in which the stages 101a to 101y are fixed, because it is required to connect a supply line for supplying a temperature control medium from outside. However, the heating unit using a resistance heater can be preferably used for both the configuration in which the stages 101a to 101y are fixed and the configuration in which the stages 101a to 101y are vertically moved, because it is only required to provide a conductive line for supplying power to the resistance heater.

The temperature control unit may control temperatures of the stages 101a to 101y together or individually. In the case of the temperature control unit capable of controlling temperatures individually, the objects to be processed G on the stages can be processed at a uniform temperature while preventing variation of temperatures in upper portions, lower portions and intermediate portions of the stages.

### Fourth Embodiment

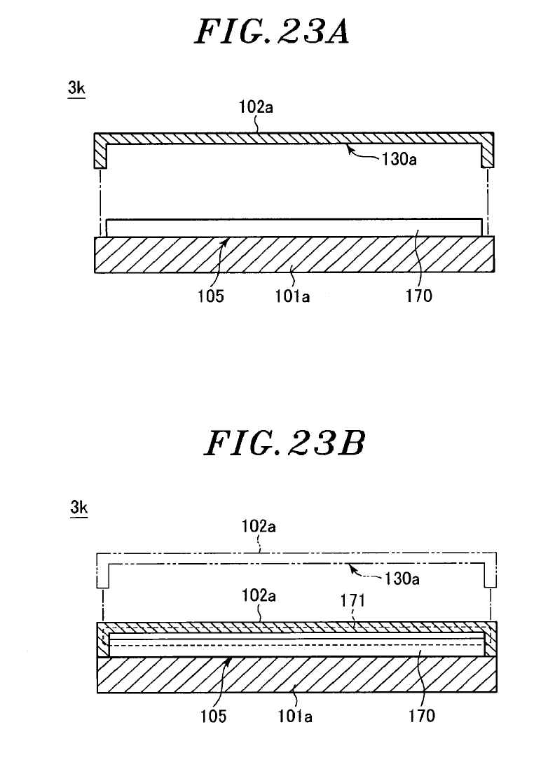

FIG. 22 is a cross sectional view showing a stage and a cover of a batch type processing apparatus in accordance with an example of a fourth embodiment of the present invention and a vicinity thereof. FIGS. 23A and 23B are cross sectional views taken along line XXIII-XXIII in FIG. 22. Further, FIG. 23A shows a state where the cover is open, and FIG. 23B shows a state where the cover is closed.

As shown in FIGS. 22, 23A and 23B, a batch type processing apparatus 3k in accordance with the fourth embodiment is different from the batch type processing apparatus in accordance with the first embodiment in that a protrusion, i.e., a baffle plate 170 in the present embodiment, is further provided on the target object mounting surface 105 of the stage 101a. The fourth embodiment is substantially the same as the first embodiment except in that the baffle plate 170 is provided. The baffle plate 170 of the present embodiment extends along, e.g., the gas exhausting groove 118, in a direction intersecting with, e.g., perpendicular to the gas flow in the small processing space 106 so as to traverse the target object mounting surface 105 (see FIG. 23A). Further, the height of the baffle plate 170 is set to be lower than that of the small processing space 106. Therefore, when the small processing space 106 is formed by the contact between the stage 101a and the cover 102a, a slit-shaped gap is formed in the small processing space 106, i.e., between the inner surface of the recess 130a and the top surface of the baffle plate 170 in the present embodiment (see FIGS. 22 and 23B). The slit-shaped gap is formed in a direction intersecting with, e.g., perpendicular to the gas flow in the small processing space, so that the small processing space 106 and the gas exhausting groove 118 communicate with each other. Accordingly, the gas supplied into the small processing space 106 is exhausted from the small processing space 106 toward the gas exhausting groove 118 via the slit-shaped gap. Due to the slit-shaped gap, the gas supplied in the small processing space 106 can become uniform compared to when the gas is directly guided to the gas exhausting groove 118. Hence, the slit-shaped gap can serve as a rectifying unit 171 for rectifying the gas flow in the small processing space 106 into, e.g., a laminar flow, by properly adjusting the size of the slit-shaped gap by adjusting the height of the baffle plate 170 or the like.

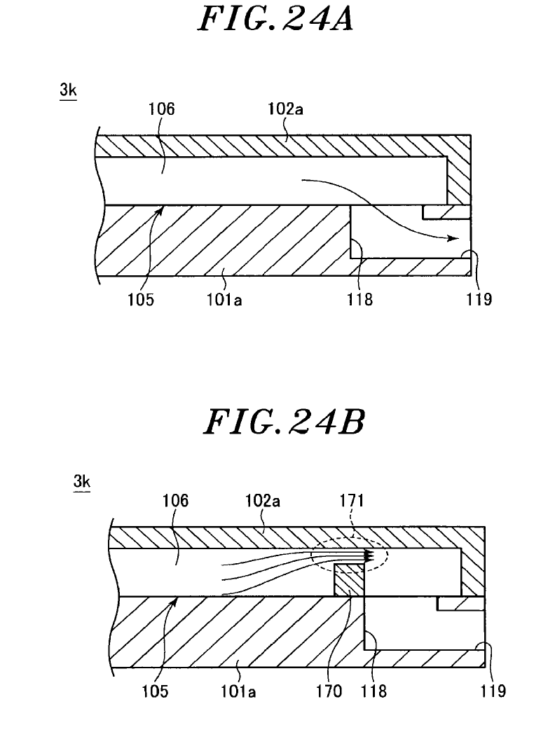

FIGS. 24A and 24B are enlarged cross sectional views showing the vicinity of the gas exhausting groove 118. FIG. 24A shows a case in which the baffle plate 170 is not provided, whereas FIG. 24B shows a case in which the baffle plate 170 is provided.

When the baffle plate 170 is not provided as shown in FIG. 24A, the gas supplied into the small processing space 106 is guided to the large gas exhausting groove 118.

On the other hand, when the baffle plate 170 is provided as shown in FIG. 24B, the slit-shaped gap of the present embodiment serves as the rectifying unit 171. The conductance of the rectifying unit 171 is smaller compared to when the baffle plate 170 is not provided. By reducing the conductance, the flow rate of the gas supplied into the small processing space 106 is restricted by the rectifying unit 171 compared to when the baffle plate 170 is not provided.

By providing the rectifying unit 171 in the small processing space 106 and restricting the gas flow rate, the rectifying function of rectifying the gas in the small processing space 106 can be realized. By utilizing the rectifying function, the laminar gas flow can be more uniformly formed in the small processing space 106.

In accordance with the batch type processing apparatus 3k of the fourth embodiment, since the rectifying unit 171 is provided in the small processing space 106, a more uniform laminar gas flow can be formed in the small processing space 106, and controllability of a film thickness and a film quality of a thin film formed on the object to be processed G can be further improved compared to when the baffle plate 170 is not provided. In addition to the above effects, it is possible to obtain the effect in which the in-plane uniformity of the film thickness and the film quality in the object to be processed G can be further improved.

### Fourth Embodiment: First Modification

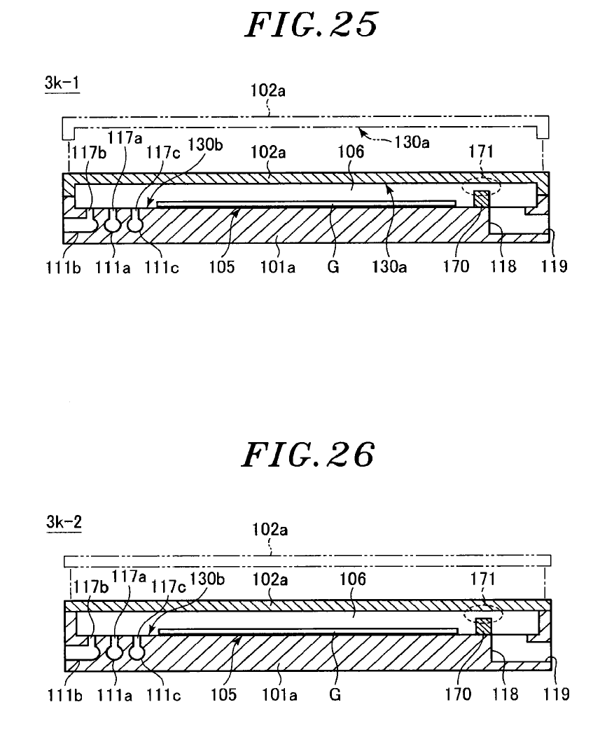

FIG. 25 is a cross sectional view showing a stage and a cover of a batch type processing apparatus in accordance with a first modification of the fourth embodiment;

As shown in FIG. 25, a batch type processing apparatus 3k-1 in accordance with a first modification is different from the batch type processing apparatus 3k in accordance with an example shown in FIG. 22 or the like in that the small processing space 106 is formed by the recess 130b formed at the stage 101a and the recess 130a formed at the cover 102a. The other configurations are substantially the same as those of the batch type processing apparatus 3k in accordance with the above-described example.

The baffle plate 170 can also be provided at the batch type processing apparatus 3k-1 in which the recesses (‘130a’ and ‘130b’ in FIG. 25) forming the small processing space 106 are formed at both of the stage 101a and the cover 102a. Further, the batch type processing apparatus 3k-1 in accordance with the first embodiment can provide the same advantages as those of the batch type processing apparatus 3k in accordance with the above-described example.

### Fourth Embodiment: Second Modification

FIG. 26 is a cross sectional view showing a stage and a cover of a batch type processing apparatus in accordance with a second modification of the fourth embodiment;

As shown in FIG. 26, a batch type processing apparatus 3k-2 in accordance with the second modification is different from the batch type processing apparatus 3k in accordance with the example shown in FIG. 22 or the like in that the cover 102a is flat and the recess 130b forming the small processing space 160 is formed at the stage 101a. The other configurations are substantially the same as those of the batch type processing apparatus 3k in accordance with the above-described example.

The baffle plate 170 can also be provided at the batch type processing apparatus 3k-2 in which the recess (‘130b’ in FIG. 26) forming the small processing space 106 is formed only at the stage 101a.

### Fourth Embodiment: Third Modification

FIG. 27 is a cross sectional view showing a stage and a cover of a batch type processing apparatus in accordance with a third modification of the fourth embodiment;

As shown in FIG. 27, a batch type processing apparatus 3k-3 in accordance with the third modification is different from the batch type processing apparatus 3k-2 in accordance with the second modification shown in FIG. 26 in that the gas supply into and the gas discharge from the small processing space 160 are performed through the side surface of the recess 130b formed at the stage 101a as in the case of the batch type processing apparatuses 3d and 3e in accordance with the second modification of the first embodiment shown in FIGS. 11B and 11C. The other configurations are substantially the same as those of the batch type processing apparatus 3k in accordance with the above-described example.

The baffle plate 170 can also be provided at the batch type processing apparatus 3k-3 in which the gas supply into and the gas discharge from the small processing space 106 are performed through the side surface of the recess 130b formed at the stage 101a. Further, the batch type processing apparatus 3k-3 in accordance with the third embodiment can provide the same advantages as those of the batch type processing apparatus 3k in accordance with the above-described example or the batch type processing apparatus 3k-2 in accordance with the second modification.

### Fourth Embodiment: Fourth Modification

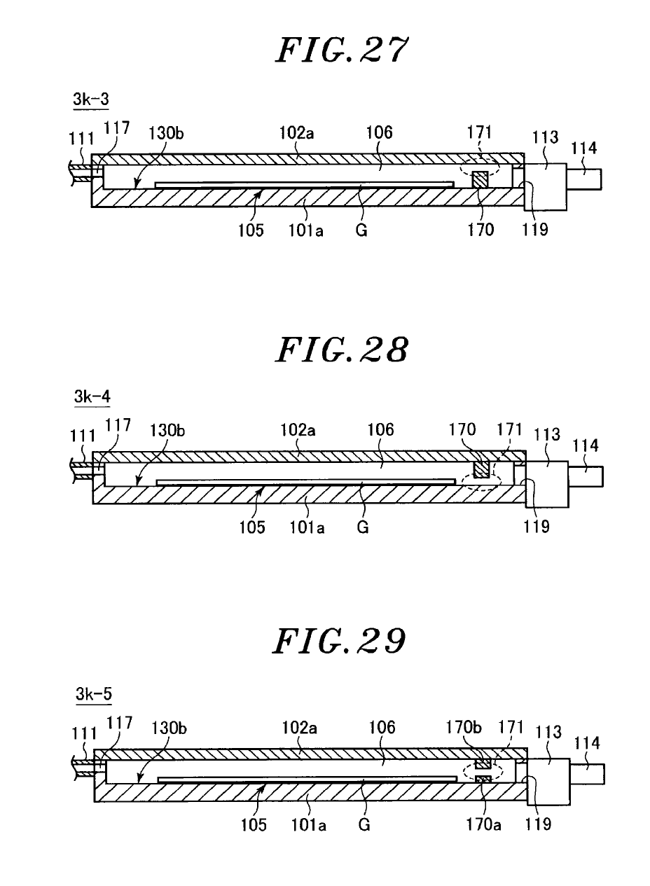

FIG. 28 is a cross sectional view showing a stage and a cover of a batch type processing apparatus in accordance with a fourth modification of the fourth embodiment;

As shown in FIG. 28, a batch type processing apparatus 3k-4 in accordance with the fourth modification is different from the batch type processing apparatus 3k-3 in accordance with the third modification shown in FIG. 27 in that the baffle plate 170 is provided on the inner surface of the cover 102a which faces the small processing space 106, instead of on the target object mounting surface 105. Accordingly, unlike the third modification in which the rectifying unit 171 is formed between the top surface of the baffle plate 170 and the inner surface of the cover 102a which faces the small processing space 106, the rectifying unit 171 of the fourth modification is formed between the bottom surface of the baffle plate 170 and the target object mounting surface 105 of the stage 101a.

The baffle plate 170 is not necessarily provided on the target object mounting surface 105 and may be provided on the inner surface of the cover 102a which faces the small processing space 106. Further, the batch type processing apparatus 3k-4 in accordance with the fourth embodiment can provide the same advantages as those of the batch type processing apparatus 3k-3 in accordance with the third modification or the like.

Moreover, the advantages of the fourth modification include the following advantage.

For example, in the case of providing the rectifying unit 171 between the top surface of the baffle plate 170 and the inner surface of the cover 102a which faces the small processing space 106 as in the third modification shown in FIG. 27, if the rectifying unit 171 is positioned too high when seen from the object to be processed G, the processing gas may pass above the surface to be processed of the object to be processed G or the concentration of the gas above the surface to be processed may decrease.

Such problem can be solved by using the fourth modification in which the rectifying unit 171 is formed between the bottom surface of the baffle plate 170 and the target object mounting surface 105 of the stage 101a.

The fourth modification can also be applied to the example of the fourth embodiment shown in FIG. 22, the first modification of the fourth embodiment shown in FIG. 25 and the second modification of the fourth embodiment shown in FIG. 26.

### Fourth Embodiment: Fifth Modification

FIG. 29 is a cross sectional view showing a stage and a cover of a batch type processing apparatus in accordance with a fifth modification of the fourth embodiment;

As shown in FIG. 29, a batch type processing apparatus 3k-5 in accordance with the fifth modification is different from the batch type processing apparatus 3k-3 in accordance with the third modification shown in FIG. 27 in that a baffle plate 170a is provided on the target object mounting surface 105 and a baffle plate 170b is provided on the inner surface of the cover 102a which faces the small processing space 106. As a consequence, in the fifth modification, the rectifying unit 171 is formed between the top surface of the baffle plate 170a and the bottom surface of the baffle plate 170b.

The baffle plates 170a and 170b can be provided at on the target object mounting surface 105 of the stage 101a and on the inner surface of the cover 102a which faces the small processing space 106, respectively. Further, the batch type processing apparatus 3k-5 in accordance with the fifth embodiment can provide the same advantages as those of the batch type processing apparatus 3k-3 in accordance with the third modification or the like.

In accordance with the fifth modification as well as the fourth embodiment, it is possible to avoid the possibility in which the processing gas passes above the surface to be processed of the object to be processed G or the concentration of the gas above the surface to be processed decreases.

In accordance with the fifth modification, the baffle plates 170a and 170b are provided on the target object mounting surface 105 of the stage 101a and the inner surface of the small processing space 106 of the cover 102a, respectively. Therefore, compared to the third modification or the fourth modification, the rectifying unit 171 can be positioned near the space above the surface to be processed of the object to be processed G. Accordingly, a more uniform laminar gas flow can be formed in the small processing space 106 and, further, the concentration of the gas can be precisely controlled. When the concentration of the gas can be precisely controlled, it is possible to control, e.g., a film forming speed, in addition to controllability of a film thickness and a film quality of a thin film and in-plane uniformity of the object to be processed G. Hence, in accordance with the fifth modification, a throughput, for example, can be improved by controlling the film forming speed.

The fifth modification can also be applied to the example of the fourth embodiment shown in FIG. 22, the first modification of the fourth embodiment shown in FIG. 25 and the second modification of the fourth embodiment shown in FIG. 26.

In addition, the example of the fourth embodiment and the first to the fifth modification of the fourth embodiment can be applied to any of the example of the first embodiment, the first to the fifth modification of the first embodiment, the example of the second embodiment, and the example and the modification of the third embodiment.

### Fifth Embodiment

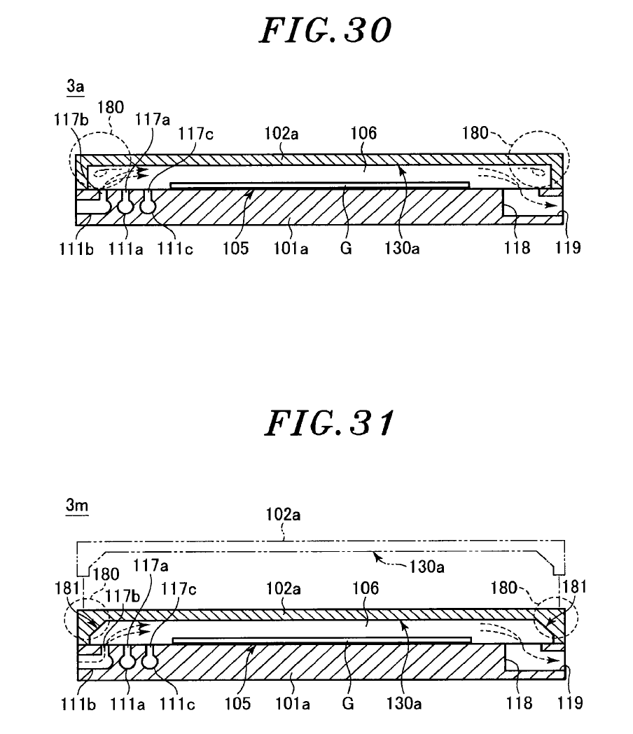

FIG. 30 is a cross sectional view showing, as a comparative example, a stage and a cover of a batch type processing apparatus in accordance with an example of the first embodiment.

As shown in FIG. 30, when the processing gas is supplied from or discharged from the target object mounting surface 105 as in the batch type processing apparatus 3a in accordance with an example of the first embodiment, the gas may stay in a corner space 180 of the small processing space 106. Although the amount of the gas staying in the corner space 180 is small, if the staying gas is a precursor, a gas phase reaction occurs when a next gas flows, and a small amount of particles is generated in the small processing space 106. Such possibility can be reduced by sufficiently performing, e.g., evacuation and purge.

However, even if evacuation and purge are sufficiently performed, a very small amount of gas may stay in the corner spaces 180. Due to high precision of future processes, even the very small amount of staying gas and particles may greatly affect the process.

The fifth embodiment is intended to provide a batch type processing apparatus capable of suppressing staying of gas in the corner space 180 and dealing with high precision of future processes.

FIG. 31 is a cross sectional view showing a stage and a cover of a batch type processing apparatus in accordance with an example of the fifth embodiment of the present invention;

As shown in FIG. 31, a batch type processing apparatus 3m in accordance with an example of the fifth embodiment is different from the batch type processing apparatus 3a in accordance with an example of the first embodiment in that a sloped portion 181 inclined with respect to the inner surface of the cover 102a which faces the small processing space 106 is formed at, e.g., the corner portion of the small processing space 106, in order to prevent the gas from staying in the corner space 180. The other configurations except that the sloped portion 181 is provided are substantially the same as those of the batch type processing apparatus 3a in accordance with an example of the first embodiment.

In accordance with the fifth embodiment, the sloped portion 181 is formed at the corner portion of the small processing space 106, so that the gas does not stay in the corner space 180 and the gas flow in the corner space 180 can be stable. Therefore, in the fifth embodiment, the amount of particles generated from the corner space 180 can be further reduced compared to when the sloped portion 181 is not formed at the corner portion.

In accordance with the batch type processing apparatus 3m of the fifth embodiment, the sloped portion 181 is formed at the corner portion of the small processing space 106, so that the amount of particles generated in the small processing space 106 can be reduced compared to when the sloped portion 181 is not formed. Further, a batch type processing apparatus capable of dealing with high precision of future processes can be achieved.

### Fifth Embodiment: First Modification

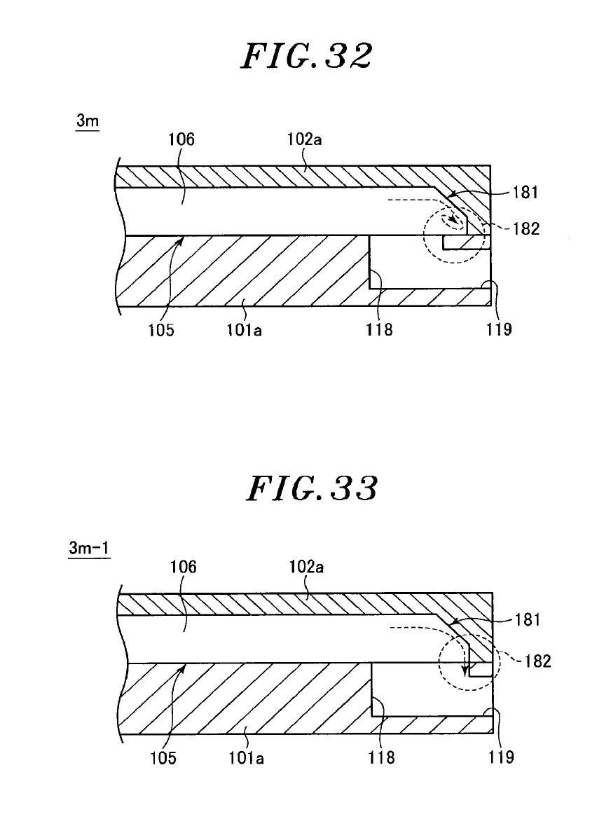

FIG. 32 is an enlarged cross sectional view showing a vicinity of a gas exhausting groove 118 of the batch type processing apparatus 3m in accordance with an example of the fifth embodiment.

As shown in FIG. 32, the batch type processing apparatus 3m in accordance with an example of the fifth embodiment is different from the batch type processing apparatus 3a in accordance with an example of the first embodiment in that the sloped portion 181 is formed at the corner portion of the small processing apparatus 106. In the batch type processing apparatus 3a, when the stage 101a and the cover 102a are brought into contact with each other, the gas exhausting groove 118 and the side portion of the cover 102a are separated from each other as indicated within a dashed circle 182. In the separated portion, a stepped portion is formed with respect to the gas flow direction by the target object mounting surface 105 between the small processing space 106 and the gas exhausting groove 118 along the gas flow direction. Accordingly, the gas may stay at the stepped portion as in the corner space 180.

The first modification intends to solve the problem in which the gas stays at the portion where the gas exhausting groove 118 and the side portion of the cover 102a are separated from each other.

FIG. 33 is a cross sectional view showing a vicinity of the gas exhausting groove of the batch type processing apparatus in accordance with the first modification of the fifth embodiment. The cross sectional view of FIG. 33 shows enlarged vicinity of the gas exhausting groove 118, as in FIG. 32.

As shown in FIG. 33, a batch type processing apparatus 3m-1 in accordance with the first modification is different from the batch type processing apparatus 3m shown in FIG. 32 in that the circumference of the gas exhausting groove 18 and the side surface of the cover 102 which faces the inner surface are coincided with each other without separating the gas exhausting groove 118 and the side surface of the cover 102a as indicated within the dashed circle. With the above configuration, in the batch type processing apparatus 3m-1 in accordance with the first modification, the gas flowing from the small processing space toward the gas exhausting groove 118 is rapidly guided to the gas exhausting groove 118 without being disturbed by the target object mounting surface 108 as shown in FIG. 32.

In accordance with the first modification, the gas exhausting groove 118 and the side surface of the cover 102a which faces the inner surface are coincided with each other, so that the gas can be guided from the small processing space 106 to the gas exhausting groove 118 and the gas can be prevented from staying above the target object mounting surface 105 between the gas exhausting groove 118 and the side portion of the cover 102a.

Therefore, the batch type processing apparatus 3m-1 in accordance with the first modification can suppress the generation of particles from the space above the target object mounting surface 105 between the gas exhausting groove 118 and the side portion of the cover 102a and reduce the amount of particles generated in the small processing space 106, compared to the batch type processing apparatus 3m in accordance with the example.

The design in which the circumference of the gas exhausting groove 118 and the side surface of the cover 102a which faces the inner surface are coincided with each other is not limited to the fifth embodiment, and may also be applied to any of the above-described embodiments in which the sloped portion 181 is not formed at the corner portion of the small processing space 106.

### Fifth Embodiment: Second Modification

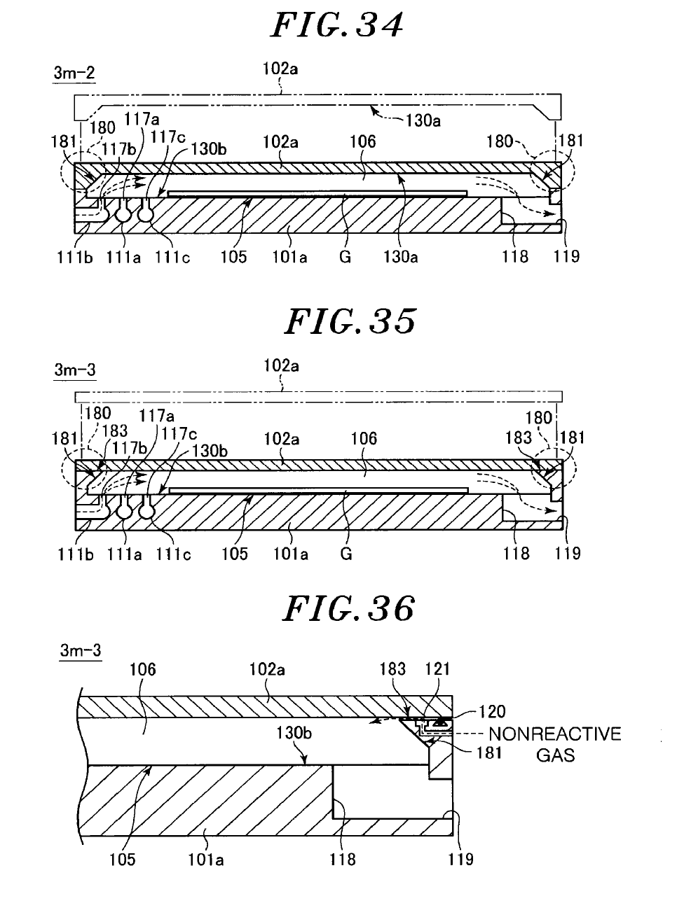

FIG. 34 is a cross sectional view showing a stage and a cover of a batch type processing apparatus in accordance with a second modification of the fifth embodiment.

As shown in FIG. 34, a batch type processing apparatus 3m-2 in accordance with the second modification of the fifth embodiment is different from the batch type processing apparatus 3m-1 in accordance with the first modification shown in FIG. 33 in that the small processing space 106 is formed by the recess 130b formed at the stage 101a and the recess 130a formed at the cover 102a. The other configurations are substantially the same as those of the batch type processing apparatus 3m-1 in accordance with the first modification.

The sloped portion 181 can be provided at the batch type processing apparatus 3m-2 in which the recesses (‘130a’ and ‘130b’ in FIG. 34) forming the small processing space 106 are formed at the stage 101a and the cover 102a, respectively. Further, the batch type processing apparatus 3m-2 in accordance with the second embodiment can provide the same advantages as those of the batch type processing apparatus 3m-1 in accordance with the first modification.

### Fifth Embodiment: Third Modification

FIG. 35 is a cross sectional view showing a stage and a cover of a batch type processing apparatus in accordance with a third modification of the fifth embodiment;

As shown in FIG. 35, a batch type processing apparatus 3m-3 in accordance with the third modification is different from the batch type processing apparatus 3m-1 in accordance with the first modification shown in FIG. 33 in that the cover 102a is flat and the recess 130b forming the small processing space 106 is formed at the stage 101a. The other configurations are substantially the same as those of the batch type processing apparatus 3m-1 in accordance with the first example.

The sloped portion 181 can be provided at the batch type processing apparatus 3m-3 in which the recess (‘130b’ in FIG. 35) forming the small processing space 106 is formed only at the stage 101a. Further, the batch type processing apparatus 3m-3 in accordance with the third embodiment can provide the same advantages as those of the batch type processing apparatus 3m-1 in accordance with the first modification.

In the third modification, the sloped portion 181 is formed at, e.g., the side portion of the recess 130b of the stage 101a. Thus, a minute gap 183 is formed at an abutting surface between the top surface of the side portion of the recess 130b and the cover 102a. Since the minute gap 183 is formed along the inner surface of the cover 102a which faces the small processing space 106, the processing gas may easily intrude into the minute gap 183.

In order to prevent the gas from intruding into the minute gap 183, as shown in FIG. 36, it is preferable to use the design employed in the batch type processing apparatus 3c in accordance with the first modification of the first embodiment described with reference to FIGS. 10A and 10B. For example, when the sloped portion 181 is formed at the top surface of the sidewall of the recess 130b, the width of the top surface is increased. Thus, an O-ring 120 is formed on the top surface, and an annular groove 121 is formed between the O-ring 120 and the small processing space 106. Further, a nonreactive gas is supplied to the annular groove 121. Accordingly, a gas that tends to intrude into the minute gas can be returned to the small processing space 106 by the nonreactive gas, or can be guided to the annular groove 121 so as to be exhausted together with the nonreactive gas via the gas exhaust line 114 (not shown) or the like.

Preferably, the third modification is used together with the first modification of the first embodiment.

### Fifth Embodiment: Fourth Modification

FIG. 37 is a cross sectional view showing a stage and a cover of the batch type processing apparatus in accordance with the fourth modification of the fifth embodiment of the present invention.

As shown in FIG. 37, a batch type processing apparatus 3m-4 in accordance with the fourth modification is different from the batch type processing apparatus 3m-1 in accordance with the first modification shown in FIG. 33 in that a rounded portion 184 is provided at the corner portion of the small processing space 106, i.e., at the inner surface of the cover 102a which faces the small processing space 106 is provided, instead of the sloped portion 181. The other configurations are substantially the same as those of the batch type processing apparatus 3m-1 in accordance with the first modification.

By providing the rounded portion 184 at the corner portion of the small processing space 106, the gas can be prevented from staying in the corner space 180. Moreover, the gas flow in the corner space 180 can be stably formed.

Therefore, as in the example of the fifth embodiment and the first to the third modification of the fifth embodiment, the fourth embodiment can reduce the amount of particles generated from the corner space 180 compared to when the rounded portion 184 is not formed at the corner portion.

Moreover, the fourth modification can be applied to the example of the fifth embodiment shown in FIG. 31, the second modification of the fifth embodiment shown in FIG. 33, the second modification of the fifth embodiment shown in FIG. 34, and the third modification of the fifth embodiment shown in FIG. 35.

Furthermore, the example of the fifth embodiment and the first to the fourth modification of the fifth embodiment can be applied to any of the example of the first embodiment, the first to the fifth modification of the first embodiment, the example of the second embodiment, the example of the third embodiment, and the example and the first to the fifth embodiment of the fourth embodiment.

### Sixth Embodiment

FIG. 38 is a cross sectional view showing a stage and a cover of the batch type processing apparatus in accordance with an example of the first embodiment;

In the first embodiment, the temperature control unit provided at the stage 101a is not illustrated. In FIG. 38, the temperature control unit is schematically illustrated.

As shown in FIG. 38, a stage temperature control unit 190 is provided in the stage 101a. The stage temperature control unit 190 includes one of or both of a heating unit using, e.g., a heater or the like, and a cooling unit using a coolant, e.g., a heat medium such as water or the like. In FIG. 38, a chiller is illustrated as a representative example, and a heat medium path 191 for flowing a heat medium is schematically illustrated.

By providing the stage temperature control unit 190 in the stage 101a, for example, the temperature control such as heating or cooling of the object to be processed G mounted on the target object mounting surface 105 can be performed by controlling the temperature of the stage 101a. In the first to the fifth embodiment, although the stage 101a is provided with the stage temperature control unit 190, the cover 102a is not provided with a temperature control unit.

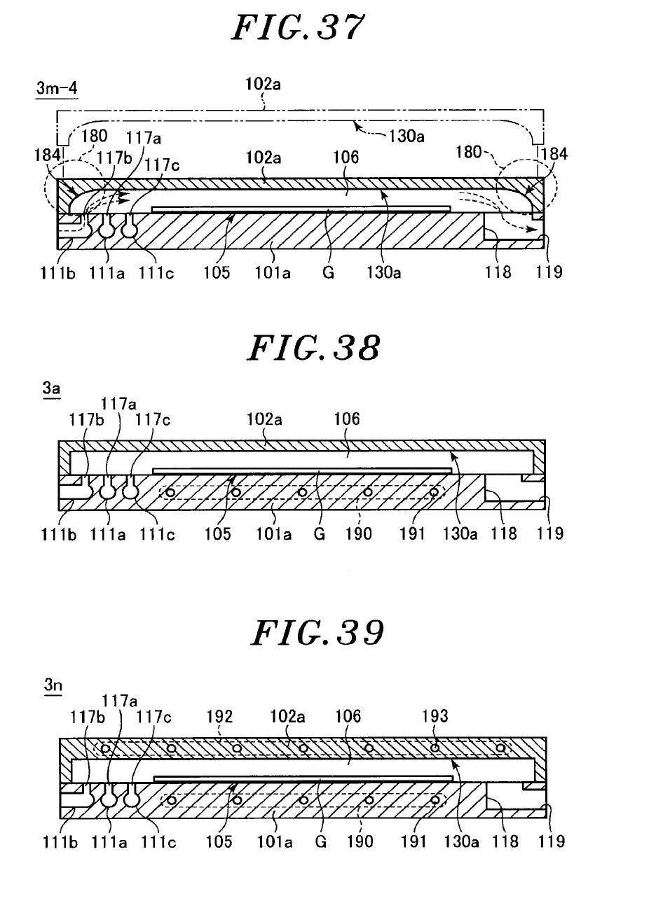

FIG. 39 is a cross sectional view showing a stage and a cover of a batch type processing apparatus in accordance with an example of a sixth embodiment of the present invention.

As shown in FIG. 39, a batch type processing apparatus 3n in accordance with an example of the sixth embodiment is different from the batch type processing apparatus 3a in accordance with the example of the first embodiment in that a cover temperature control unit 192 for controlling a temperature of the cover 102a is provided at the cover 102a in addition to the stage temperature control unit 190. The other configurations are substantially the same as those of the batch type processing apparatus 3a in accordance with the example of the first embodiment.

The cover temperature control unit 192 is provided in the cover 102a, for example, and includes one of or both of a heating unit using, e.g., a heater or the like, and a cooling unit using a coolant, e.g., a heat medium such as water or the like, as in the stage temperature control unit 190. In FIG. 39, a chiller is illustrated as a representative example, and a heat medium path 193 for flowing a heat medium is schematically illustrated.

In the example of the sixth embodiment, the stage temperature control unit 190 and the cover temperature control unit 192 are configured to control temperatures individually. Since the stage temperature control unit 190 and the cover temperature control unit 192 can perform individual temperature control, the temperature of the stage 101a and the temperature of the cover 102a can be controlled to different temperatures.

In accordance with the sixth embodiment, the following advantages can be obtained.

For example, when an object to be processed G is subjected to a vacuum processing or low-pressure processing while setting a pressure in the small processing space 106 to be lower than, e.g., the atmospheric pressure (=101325 Pa), the heat transfer medium in the small processing space 106 is actually lost or reduced compared to a case under the atmospheric pressure. For that reason, when the temperature is controlled only by the stage temperature control unit 190, the heat is not transferred or hardly transferred to the cover 102a. As a consequence, the temperature of the cover 102a becomes lower than that of the stage 101a. For example, when film formation that is originally performed at a high temperature is carried out at a low temperature, deposits different from deposits generated by the original film formation may be deposited on the inner surface of the cover 102a which faces the small processing space 106. When the film formation is performed by deposition of deposits on the inner surface at a low temperature, it causes generation of particles in the small processing space 106.

In the sixth embodiment, since the cover 102a is provided with the cover temperature control mechanism 192, the temperature of the cover 102a can be controlled to a level at which deposits are hardly deposited or not deposited. By controlling the temperature of the cover 102a with the cover temperature control unit 192, the generation of particles on the inner surface of the cover 102a which faces the small processing space 106 can be suppressed.

Since the generation of deposits can be suppressed, the possibility in which particles are generated in the small processing space 106 can be further reduced compared to when the cover temperature control unit 192 is not provided.

When the cover temperature control unit 192 is not provided, a processing temperature, e.g., a film formation temperature, needs to be restricted within a certain range in order to suppress generation of deposits in the small processing space 106. When the temperature is restricted, the process window is reduced, which leads to decrease of the universality of the batch type processing apparatus.

In accordance with the sixth embodiment, the cover temperature control unit 192 is provided, so that the generation of deposits in the small processing space 106 can be suppressed even if the processing temperature, e.g., the film formation temperature, is not restricted within a certain range. Further, in the sixth embodiment, the temperature of the stage 101a and that of the cover 102a can be individually controlled. Accordingly, the following various temperature settings can be achieved:
(1) temperature of the stage 101a>temperature of the cover 102a;
(2) temperature of the stage 101a<temperature of the cover 102a;
(3) temperature of the stage 101a=temperature of the cover 102a.

In accordance with the sixth embodiment, various temperatures can be set to the stage 101a and the cover 102a. As a result, the process window can be increased, and the universality of the batch type processing apparatus can be further improved.

The batch type processing space 3n in accordance with an example of the sixth embodiment can provide advantages in which particles generated in the small processing space 106 can be reduced and the process window can be increased. Thus, the batch type processing space 3n in accordance with an example of the sixth embodiment can effectively deal with the high precision of future processes.

An example of the sixth embodiment can be applied to any of an example of the first embodiment, a first to a fifth modification of the first embodiment, an example of the second embodiment, an example and a modification of the third embodiment, an example and a first to a fifth modification of the fourth embodiment, and a first to a fourth modification of the fifth embodiment.

While the present invention has been described with reference to the embodiments, the present invention can be variously modified without being limited to the above-described embodiments.

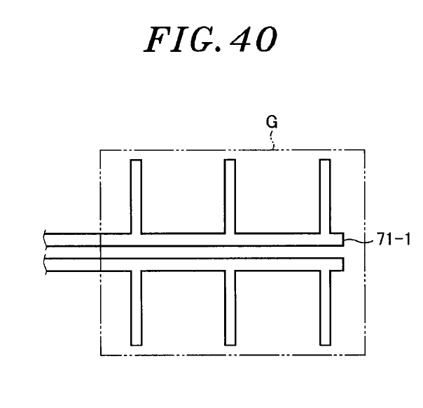

For example, the pick 71 of the transfer unit 7 is not limited to a fork-shaped pick, and a fish bone-shaped pick 71-1 shown in FIG. 40 can also be used.

In the above-described embodiments, as for a batch type processing apparatus, a film forming apparatus using an ALD method or a MLD method is used. However, the present invention can also be applied to a gas film formation apparatus only using a gas, a heat CVD apparatus, a gas etching apparatus only using a gas, a vacuum bake apparatus or the like.

The present invention can be applied to the plasma processing apparatus. When treatment using a plasma is performed, it is preferable to use a remote plasma type in which a plasma generated in a space different from the small processing space 106 is supplied to the small processing space 106. By using the remote plasma type, a plasma generation unit for generating a plasma in the small processing spaces 106 becomes unnecessary. Further, the sum of the thickness of the stages 101 and the thickness of the covers 102 can be reduced, and the number of the stages 101 and the covers 102 which can be accommodated in the main chamber can be increased without scaling up the main chamber in a height direction. This is effective when the number of objects to be processed G that can be processed at one time needs to be increased.

In the above description, the gas exhaust port 119 is provided at one location. However, the gas exhaust port 119 may be provided at a plurality of locations.

When a temperature control unit, e.g., a chiller, a heater or the like, for controlling a temperature of an object to be processed G, is provided at the stage 101, the temperature control medium of the chiller may be a water cooled type or an air cooled type. Further, a conventional heating element can be used as the heater.

In addition, the present invention can be variously modified without departing from the scope thereof.

1. A batch type processing apparatus for simultaneously processing a plurality of target objects to be processed, comprising:
a main chamber;
a plurality of stages, arranged in the main chamber in a height direction of the main chamber, for mounting thereon the target objects; and
a plurality of covers, provided to the stages, for covering the target objects mounted on the stages,
wherein the stages and the covers surround the target objects mounted on the stages, thereby forming small processing spaces each of which has a capacity smaller than a capacity of the main chamber
wherein the batch type processing apparatus further comprises a nonreactive gas injection unit at a groove formed at contact surfaces between top surfaces of the stages and lower ends of the covers for injecting a nonreactive gas to the groove.

2. The batch type processing apparatus of claim 1, further comprising:
a driving unit for vertically moving the covers or the stages;
a target object elevation unit for vertically moving the target objects between target object mounting surfaces of the stages and spaces above the target object mounting surfaces;
a gas supply unit for supplying a gas into the small processing spaces; and
a gas exhaust unit for exhausting the small processing spaces,
wherein the stages are fixed to the main chamber, and the driving unit vertically moves the covers, and
wherein the gas supply unit and the gas exhaust unit are provided to each of the stages.

3. The batch type processing apparatus of claim 2, wherein the target object elevation unit is separated from the driving unit.

4. The batch type processing apparatus of claim 3, wherein recesses forming the small processing spaces are formed at target object mounting surfaces of the stages.

5. The batch type processing apparatus of claim 4, wherein the surfaces of the covers which face the stages are flat.

6. The batch type processing apparatus of claim 4, wherein recesses forming the small processing spaces are formed at the surfaces of the covers which face the stages.
